(19) United States
(12) Patent Application Publication
(10) Pub. No.: US 2023/0326864 A1
(43) Pub. Date: Oct. 12, 2023

(54) SEMICONDUCTOR DEVICE

(71) Applicant: SUMITOMO ELECTRIC INDUSTRIES, LTD., Osaka (JP)

(72) Inventors: Tatsushi KANEDA, Osaka (JP); Hirotaka OOMORI, Osaka (JP)

(21) Appl. No.: 17/909,428

(22) PCT Filed: Mar. 11, 2021
(86) PCT No.: PCT/JP2021/009789

§ 371 Date: Sep. 5, 2022

(30) Foreign Application Priority Data
Mar. 12, 2020 (JP) 2020-042613
Sep. 18, 2020 (JP) 2020-157444

(51) Int. Cl. H01L 23/538; H01L 25/18; H01L 23/00

(52) U.S. Cl. CPC H01L 23/5386; H01L 25/18; H01L 24/49; H01L 24/48; H01L 2224/48227; H01L 2224/49175; H01L 2924/13091; H01L 2924/12032; H01L 24/32; H01L 2224/32225; H01L 24/73; H01L 2224/73265; H01L 23/3735

(57) ABSTRACT

A semiconductor device includes a substrate, a circuit pattern, a P-terminal, an N-terminal, an O-terminal, a first transistor chip, a second transistor chip, a first diode chip, and a second diode chip. The circuit pattern includes a first region, a second region, and a third region. The third region includes a band-shaped first branch portion, a band-shaped second branch portion, and a connection portion. The first transistor chip is mounted on the first region. The second transistor chip is mounted on the second branch portion. The first diode chip is mounted on the first region. The second diode chip is mounted on the second branch portion. The first transistor chip and the first diode chip are disposed side by side along a first direction. The second transistor chip and the second diode chip are disposed side by side along the first direction.

### TECHNICAL FIELD

The present disclosure relates to a semiconductor device.

The present application claims priority based on Japanese Patent Application No. 2020-42613 filed on Mar. 12, 2020 and Japanese Patent Application No. 2020-157444 filed on Sep. 18, 2020, the entire contents of which are incorporated herein by reference.

### BACKGROUND ART

A semiconductor device which has a P-terminal, an N-terminal, and an O-terminal and in which a plurality of semiconductor chips are mounted on a circuit pattern is disclosed (see, for example, Patent Literatures 1 and 2).

### CITATION LIST

### Patent Literature

Patent Literature 1: Japanese Patent Application Publication No. 2015-154079

Patent Literature 2: Japanese Patent Application Publication No. 2017-220627

### SUMMARY OF INVENTION

A semiconductor device according to the present disclosure includes: an insulating substrate; a circuit pattern disposed on the substrate; a P-terminal, an N-terminal, and an O-terminal electrically connected to the circuit pattern; a first transistor chip and a second transistor chip mounted on the circuit pattern; and a first diode chip and a second diode chip mounted on the circuit pattern. The circuit pattern includes a band-shaped first region electrically connected to the P-terminal and extending along a first direction, a band-shaped second region electrically connected to the N-terminal, spaced from the first region in a second direction, and extending along the first direction, the second direction being a width direction of the first region, and a third region electrically connected to the O-terminal and spaced from each of the first region and the second region. The third region includes a band-shaped first branch portion extending along the first direction, a band-shaped second branch portion spaced from the first branch portion in the second direction and extending along the first direction, and a connection portion extending along the second direction and connecting one end of the first branch portion and one end of the second branch portion. The first transistor chip is mounted on the first region to be electrically connected to the first region, and electrically connected to the first branch portion by a first wire. The second transistor chip is mounted on the second branch portion to be electrically connected to the second branch portion, and electrically connected to the second region by a second wire. The first diode chip is mounted on the first region to be electrically connected to the first region, and electrically connected to the first branch portion by a connection member. The second diode chip is mounted on the second branch portion to be electrically connected to the second branch portion, and electrically connected to the second region by a connection member. The first transistor chip and the first diode chip are disposed side by side along the first direction. The second transistor chip and the second diode chip are disposed side by side along the first direction.

### BRIEF DESCRIPTION OF DRAWINGS

FIG. 1 is a schematic plan view of a semiconductor device according to a first embodiment when seen in the thickness direction of a substrate.

FIG. 2 is a plan view schematically illustrating only the substrate and a circuit pattern included in the semiconductor device illustrated in FIG. 1.

FIG. 3 is a cross-sectional view schematically illustrating a part of the semiconductor device illustrated in FIG. 1.

FIG. 4 is a plan view schematically illustrating a flow of a current in a first state in the semiconductor device according to the first embodiment illustrated in FIG. 1.

FIG. 5 is a plan view schematically illustrating a flow of a current in a second state in the semiconductor device according to the first embodiment illustrated in FIG. 1.

FIG. 6 is an enlarged view of a part of the semiconductor device illustrated in FIG. 1.

FIG. 7 is a schematic plan view of a semiconductor device according to a second embodiment when seen in the thickness direction of a substrate.

FIG. 8 is a schematic plan view of a semiconductor device according to a third embodiment when seen in the thickness direction of a substrate.

FIG. 9 is a schematic plan view of a semiconductor device according to a fourth embodiment when seen in the thickness direction of a substrate.

FIG. 10 is a plan view schematically illustrating a flow of a current in a forward direction in the semiconductor device according to the fourth embodiment illustrated in FIG. 9.

FIG. 11 is a plan view schematically illustrating a flow of a current in a reverse direction in the semiconductor device according to the fourth embodiment illustrated in FIG. 9.

FIG. 12 is a schematic plan view of a semiconductor device according to a fifth embodiment when seen in the thickness direction of a substrate.

### DESCRIPTION OF EMBODIMENTS

### Technical Problem

In the case of operating the semiconductor device disclosed in Patent Literature 1 or 2 as an inverter, for example, a first state and a second state are alternately repeated at high speed. Specifically, in the first state, electrical connection between the P-terminal and the O-terminal is on and electrical connection between the O-terminal and the N-terminal is off, and in the second state, electrical connection between the P-terminal and the O-terminal is off and electrical connection between the O-terminal and the N-terminal is on. In this manner, an output close to a desired alternating-current (AC) waveform is obtained. It is required to facilitate control for obtaining an output close to a desired DC waveform.

It is therefore an object to provide a semiconductor device that facilitates control for obtaining an output close to a desired AC waveform.

### Effects of the Disclosure

The semiconductor device described above facilitates control for obtaining an output close to a desired AC waveform.

### [Description of Embodiments of the Present Disclosure]

First, embodiments of the present disclosure will be listed and described. A semiconductor device according to the present disclosure includes: an insulating substrate; a circuit pattern disposed on the substrate; a P-terminal, an N-terminal, and an O-terminal electrically connected to the circuit pattern; a first transistor chip and a second transistor chip mounted on the circuit pattern; and a first diode chip and a second diode chip mounted on the circuit pattern. The circuit pattern includes a band-shaped first region electrically connected to the P-terminal and extending along a first direction, a band-shaped second region electrically connected to the N-terminal, spaced from the first region in a second direction, and extending along the first direction, the second direction being a width direction of the first region, and a third region electrically connected to the O-terminal and spaced from each of the first region and the second region. The third region includes a band-shaped first branch portion extending along the first direction, a band-shaped second branch portion spaced from the first branch portion in the second direction and extending along the first direction, and a connection portion extending along the second direction and connecting one end of the first branch portion and one end of the second branch portion. The first transistor chip is mounted on the first region to be electrically connected to the first region, and electrically connected to the first branch portion by a first wire. The second transistor chip is mounted on the second branch portion to be electrically connected to the second branch portion, and electrically connected to the second region by a second wire. The first diode chip is mounted on the first region to be electrically connected to the first region, and electrically connected to the first branch portion by a connection member. The second diode chip is mounted on the second branch portion to be electrically connected to the second branch portion, and electrically connected to the second region by a connection member. The first transistor chip and the first diode chip are disposed side by side along the first direction. The second transistor chip and the second diode chip are disposed side by side along the first direction.

Inventors studied a configuration of a semiconductor device that facilitates control for obtaining an output close to a desired AC waveform to obtain the following configuration. In the semiconductor device, in a first state where electrical connection between the P-terminal and the O-terminal is on and electrical connection between the O-terminal and the N-terminal is off, a current flows from the P-terminal to the O-terminal through the circuit pattern, the transistor chip in the ON state, and then the circuit pattern again. In a second state where electrical connection between the P-terminal and the O-terminal is off and electrical connection between the O-terminal and the N-terminal is on, a current flows from the O-terminal to the N-terminal through the circuit pattern, the transistor chip in the ON state, and then circuit pattern again. Here, in a conventional semiconductor device, with some arrangement on the circuit pattern, a current flows in a region in which transistor chips in the ON state are mounted among a plurality of transistor chips. This current flow causes heat generation in the circuit pattern.

Consequently, heat dissipation from the transistor chip is inhibited. This causes a difference in cooling speed between a transistor chip disposed in a region where a current flows and a transistor chip disposed in a region where no current flows in the circuit pattern. As a result, a temperature difference among a plurality of transistor chips increases so that electrical control for obtaining an output close to a desired AC waveform becomes complicated in high-speed switching operation. In view of this, the inventors conceived that a path in which a current flows in the circuit pattern is switched between the first state and the second state.

In the semiconductor device according to the present disclosure, in the first state, a current flows from the P-terminal to the O-terminal through a first region of the circuit pattern, a first transistor chip in an ON state, a first wire, a first branch portion of a third region of the circuit pattern, and then a connection portion of the third region of the circuit pattern. At this time, no current flows in a second branch portion of the third region of the circuit pattern on which a second transistor chip in an OFF state is mounted. Then, it is possible to suppress inhibition of heat dissipation from the second transistor chip by heat generation of the second branch portion of the third region of the circuit pattern in the first state. On the other hand, in the second state, a current flows from the O-terminal to the N-terminal through the connection portion of the third region of the circuit pattern, the second branch portion of the third region of the circuit pattern, the second transistor chip in the ON state, a second wire, and then a second region of the circuit pattern. At this time, no current flows in the first region of the circuit pattern on which the first transistor chip in the OFF state is mounted. Then, it is possible to suppress inhibition of heat dissipation from the first transistor chip by heat generation of the first region of the circuit pattern in the second state. In the manner described above, the path of a current flowing in the circuit pattern is switched between the first state and the second state. This can reduce a difference between the cooling speed of the first transistor chip in the OFF state and the cooling speed of the second transistor chip in the OFF state. Accordingly, in the semiconductor device, a temperature difference between the first transistor chip and the second transistor chip can be reduced. As a result, electrical control for obtaining an output close to a desired AC waveform can be facilitated.

In the semiconductor device according to the present disclosure, the first transistor chip and the first diode chip are disposed side by side along a first direction, and the second transistor chip and the second diode chip are arranged side by side along the first direction. This configuration can reduce density of the transistor chip and the diode chip as a heat generation source to promote uniformity of heat. Thus, the advantage of reducing a temperature difference between the transistor chip and the diode chip can be more effectively obtained. In particular, in the case of using a copper plate having high thermal conductivity as a circuit pattern, this advantage can be significantly high. This configuration can also avoid an excessive increase in size of the semiconductor device in a second direction. With this configuration, in connecting such semiconductor devices in parallel, routing of wires can be minimized.

In the semiconductor device, the first region may be divided, in the first direction, into one-side first region disposed at the one side and the other-side first region disposed at the other side, the one-side first region and the other-side first region being disposed side by side along the first direction and electrically connected to each other by a connection member. The second region may be divided, in the first direction, into one-side second region disposed at the one side and the other-side second region disposed at the other side, the one-side second region and the other-side second region being disposed side by side along the first direction and electrically connected to each other by a connection member. The first branch portion may be divided, in the first direction, into one-side first branch portion disposed at the one side and the other-side first branch portion disposed at the other side, the one-side first branch portion and the other-side first branch portion being disposed side by side along the first direction and electrically connected to each other by a connection member. The second branch portion may be divided, in the first direction, into one-side second branch portion disposed at the one side and the other-side second branch portion disposed at the other side, the one-side second branch portion and the other-side second branch portion being disposed side by side along the first direction and electrically connected to each other by a connection member. With this configuration, each of the first region, the second region, the first branch portion, and the second branch portion is branched in the first direction, and the branched portions are disposed on different substrates. Accordingly, stress occurring based on a difference between thermal expansion coefficients of members can be reduced.

The semiconductor device may further include a plurality of third diode chips and a plurality of fourth diode chips mounted on the circuit pattern. The plurality of third diode chips may be adjacent to one another along the first direction, disposed side by side with the first diode chip in the second direction, mounted on the first region to be electrically connected to the first region, and electrically connected to the first branch portion by a connection member. The plurality of fourth diode chips may be adjacent to one another along the first direction, disposed side by side with the third diode chip in the second direction, mounted on the second branch portion to be electrically connected to the second branch portion, and electrically connected to the second region by a connection member. With this configuration, a current is allowed to flow in the plurality of third diode chips in addition to the plurality of first diode chips. A current can also be allowed to flow in the plurality of fourth diode chips in addition to the plurality of second diode chips. Accordingly, the amount of a current flowing in each diode chip can be reduced. As a result, the amount of heat generation in each diode chip can be reduced so that the possibility of deterioration can be reduced.

In the semiconductor device, the first transistor chip may include a plurality of first transistor chips. The second transistor chip may include a plurality of second transistor chips. The first diode chip may include a plurality of first diode chips. The second diode chip may include a plurality of second diode chips. The plurality of first transistor chips may be adjacent to one another along the first direction. The plurality of second transistor chips may be adjacent to one another along the first direction. The plurality of first diode chips may be adjacent to one another along the first direction.

The plurality of second diode chips may be adjacent to one another along the first direction. With this configuration, the plurality of first transistor chips are concentrated so that inductance of a gate loop in each of the plurality of first transistor chips can be reduced. A difference in gate loop inductance between the first transistor chips can also be reduced. Similarly, inductance of the gate loop in each of the plurality of second transistor chips can be reduced. A difference in gate loop inductance between the second transistor chips can also be reduced. Accordingly, high-speed operation can be further stabilized. In addition, with this configuration, the plurality of first transistor chips can be concentrated and routing of wires in a control circuit for controlling operation of the plurality of first transistor chips can be facilitated so that and the control circuit for controlling the plurality of first transistor chips occupies a compact region. Then, a large region can be obtained for arrangement of the plurality of first diode chips in the second direction without an increase in the entire size so that a large number of first diode chips can be disposed. The same holds for the plurality of second transistor chips and the plurality of second diode chips. Thus, design flexibility increases, and improvement of heat dissipation and reduction of parasitic inductance can be taken into consideration.

In the semiconductor device, the plurality of first transistor chips may be mounted on the one-side first region. The plurality of first diode chips may be mounted on the other-side first region. The plurality of second transistor chips may be mounted on the other-side second branch portion. The plurality of second diode chips may be mounted on the one-side second branch portion. With this configuration, a path of a current flowing in the first transistor chips and a path of a current flowing in the first diode chips can be distinctly separated. A path of a current flowing in the second transistor chips and a path of a current flowing in the second diode chips can be distinctly separated. Thus, heat generation of the connection member connecting divided portions can be reduced, and the risk of fusing of the connection member can be reduced.

In the semiconductor device, the plurality of third diode chips may be mounted on the other -side first region. The plurality of fourth diode chips may be mounted on the one-side second branch portion. With this configuration, a current is also allowed to flow in the plurality of third diode chips in addition to the plurality of first diode chips in the other-side first region. In this case, a path of a current flowing in the third diode chips and a path of a current flowing in the first transistor chips can be separated. In the one-side second branch portion, a current is also allowed to flow in the plurality of fourth diode chips in addition to the plurality of second diode chips. In this case, a path of a current flowing in the fourth diode chips and a path of a current flowing in the second transistor chips can be separated. Accordingly, the amount of heat generation in the diode chips can be efficiently reduced.

In the semiconductor device, the first transistor chip may include a plurality of first transistor chips. The second transistor chip may include a plurality of second transistor chips. The first diode chip may include a plurality of first diode chips. The second diode chip may include a plurality of second diode chips. The plurality of first transistor chips and the plurality of first diode chips may be alternately arranged along the first direction. The plurality of second transistor chips and the plurality of second diode chips may be alternately arranged along the first direction. Transistor chips and diode chips generate heat in different ways depending on operating conditions, control conditions, and application conditions. However, when the transistor chips and the diode chips are alternately arranged in the first direction in the manner described above, uniformity of heat generation can be further enhanced.

The semiconductor device may further include: a heat dissipation plate having a first surface at one side in a thickness direction of the substrate, the substrate being mounted on the first surface; and a frame member rising from the first surface and surrounding the substrate when seen in the thickness direction of the substrate. An outer shape of the substrate may be a rectangle whose pair of longer sides extends in the first direction when seen in the thickness direction of the substrate. The frame member may include a first wall and a second wall respectively corresponding to the pair of longer sides of the substrate. The P-terminal and the N-terminal may be disposed at a side opposite to a second shorter side when seen from a first shorter side of the substrate. The O-terminal may be disposed at a side opposite to the first shorter side when seen from the second shorter side. With this configuration, the configuration of the semiconductor device according to the present disclosure can be easily obtained.

The semiconductor device may further include: a first gate terminal attached to the first wall and electrically connected to a gate pad of the first transistor chip; and a second gate terminal attached to the second wall and electrically connected to a gate pad of the second transistor chip. In the second direction, a distance between the first wall and the first region may be smaller than each of a distance between the first wall and the second region, a distance between the first wall and the first branch portion, and a distance between the first wall and the second branch portion. In the second direction, a distance between the second wall and the second branch portion may be smaller than each of a distance between the second wall and the first region, a distance between the second wall and the second region, and a distance between the second wall and the first branch portion. With this configuration, the length of a wire connecting the first gate terminal to the gate pad of the first transistor chip and the length of a wire connecting the second gate terminal to the gate pad of the second transistor chip can be reduced. Accordingly, inductance can be reduced.

The semiconductor device may further include: a first kelvin source terminal attached to the first wall and electrically connected to a kelvin source pad of the first transistor chip; and a second kelvin source terminal attached to the second wall and electrically connected to a kelvin source pad of the second transistor chip. In the second direction, a distance between the first wall and the first region may be smaller than each of a distance between the first wall and the second region, a distance between the first wall and the first branch portion, and a distance between the first wall and the second branch portion. In the second direction, a distance between the second wall and the second branch portion may be smaller than each of a distance between the second wall and the first region, a distance between the second wall and the second region, and a distance between the second wall and the first branch portion. With this configuration, the length of a wire connecting the first kelvin source terminal to the first transistor chip and the length of a wire connecting the second kelvin source terminal to the second transistor chip can be reduced. Accordingly, inductance can be reduced.

In the semiconductor device, the first gate terminal and the first kelvin source terminal may be adjacent to each other and attached to the first wall. The second gate terminal and the second kelvin source terminal may be adjacent to each other and attached to the second wall. The circuit pattern may further include a band-shaped fourth region electrically connected to the first kelvin source terminal by a connection member, spaced from the first region in the second direction, and extending along the first direction, a band-shaped fifth region electrically connected to the first gate terminal by a connection member, spaced from the fourth region in the second direction, and extending along the first direction, a band-shaped sixth region electrically connected to the second gate terminal by a connection member, spaced from the second branch portion in the second direction, and extending along the first direction, and a band-shaped seventh region electrically connected to the second kelvin source terminal by a connection member, spaced from the sixth region in the second direction, and extending along the first direction. A current direction from the first gate terminal to a gate pad of the first transistor chip in the fifth region may be opposite to a current direction from the kelvin source pad of the first transistor chip to the first kelvin source terminal in the fourth region. A current direction from the second gate terminal to a gate pad of the second transistor chip in the sixth region may be opposite to a current direction from the kelvin source pad of the second transistor chip to the second kelvin source terminal in the seventh region. With this configuration, while a current flows in a current path constituted by the first gate terminal, the fifth region of the circuit pattern, the first transistor chip, the fourth region of the circuit pattern, and the first kelvin source terminal, the direction of the current flowing between the fourth region and the fifth region spaced from each other in the second direction can be reversed. While a current flows in a current path constituted by the second gate terminal, the seventh region of the circuit pattern, the second transistor chip, the sixth region of the circuit pattern, and the second kelvin source terminal, the direction of the current flowing between the sixth region and the seventh region spaced from each other in the second direction can be reversed. Thus, inductance of these control circuits can be reduced by mutual inductance.

In the semiconductor device, the first wire may include first source connection members each electrically connecting a source pad of the first transistor chip to the first branch portion. The second wire may include second source connection members each electrically connecting a source pad of the second transistor chip to the second region. A length of each of the first source connection members may be equal to a length of each of the second source connection members. The number of the first source connection members may be equal to the number of the second source connection members. With this configuration, the values of inductance in electrical paths can be easily made uniform. Accordingly, electrical characteristics of the paths can be easily made uniform so that electrical control can be facilitated.

In the semiconductor device, at least one of the first transistor chip or the second transistor chip may include a semiconductor layer of SiC or GaN. The transistor chip including such a semiconductor layer can switch at high speed, and thus, is preferable for the semiconductor device according to the present disclosure that switches current paths.

In the semiconductor device, the first branch portion may be disposed between the first region and the second region in the second direction. The second region may be disposed between the first branch portion and the second branch portion in the second direction. With this configuration, the lengths of the connection members and wires connecting the components can be reduced. Accordingly, inductance can be further reduced.

### [Detailed Description of Embodiment of the Present Disclosure]

One embodiment of the semiconductor device according to the present disclosure will be described with reference to the drawings. In the following drawings, the same or corresponding parts are denoted by the same reference numerals, and the description thereof will not be repeated.

### FIRST EMBODIMENT

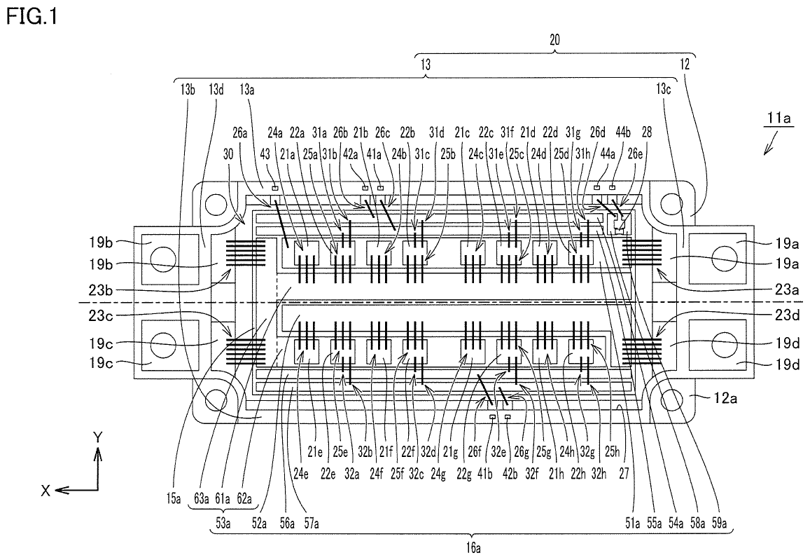

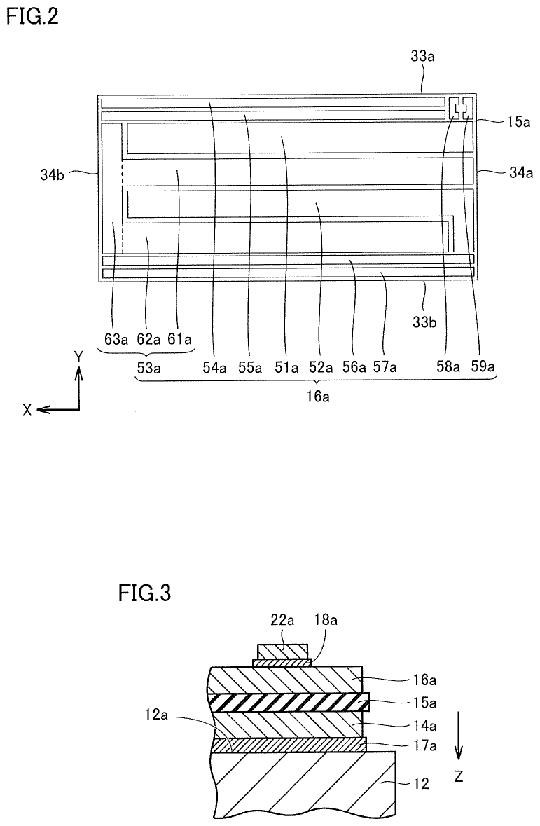

A configuration of a semiconductor device according to a first embodiment of the present disclosure will be described. FIG. 1 is a schematic plan view of the semiconductor device according to the first embodiment when seen in the thickness direction of a substrate. FIG. 2 is a plan view schematically illustrating only the substrate and a circuit pattern included in the semiconductor device illustrated in FIG. 1.

In FIG. 1, for example, a boundary between a first branch portion described later and a connection portion and a boundary between a second branch portion and a connection portion are indicated by broken lines. FIG. 3 is a cross-sectional view schematically illustrating a part of the semiconductor device illustrated in FIG. 1. FIG. 3 is a cross-sectional view including a first transistor chip and taken along a plane parallel to an X-Z plane.

With reference to FIGS. 1, 2, and 3, a semiconductor device 11a according to the first embodiment includes a heat dissipation plate 12, a frame member 13, a metal plate 14a (see FIG. 3), a substrate 15a, a circuit pattern 16a, solder portions 17a and 18a (see FIG. 3), a P-terminal 19a, O-terminals 19b and 19c, an N-terminal 19d, first diode chips 21a, 21b, 21c, and 21d, first transistor chips 22a, 22b, 22c, and 22d, second diode chips 21e, 21f, 21g, and 21h, and second transistor chips 22e, 22f, 22g, and 22h.

The heat dissipation plate 12 is made of a metal. The heat dissipation plate 12 is made of, for example, copper. A surface of the heat dissipation plate 12 may be subjected to nickel plating. The outer shape of the heat dissipation plate 12 is a rectangle whose side extending in the X direction is a longer side and whose side extending in the Y direction is a shorter side when seen in the thickness direction, and the corners of the rectangle are rounded. The heat dissipation plate 12 has a first surface 12a at one side in the thickness direction thereof, and a solder portion 17a is disposed on the first surface 12a. Examples of a material for the solder portion 17a include Sn—Ag—Cu-based solder and Sn—Sb-based solder.

The metal plate 14a is disposed on the solder portion 17a. The heat dissipation plate 12 and the metal plate 14a are coupled together by the solder portion 17a. The metal plate 14a is made of, for example, copper.

The substrate 15a is disposed on the metal plate 14a. The substrate 15a is mounted on the first surface 12a of the heat dissipation plate 12. The substrate 15a is insulative. Examples of an insulative material for the substrate 15a include Al₂O₃, AlN, and Si₃N₄. The thickness direction heat dissipation plate 12 and the thickness direction of the substrate 15a are both a Z direction. The outer shape of the substrate 15a is a rectangle whose longer side extends in the X direction that is a first direction described later, when seen in the thickness direction of the substrate 15a. Specifically, with respect especially to FIG. 2, the outer shape of the substrate 15a is constituted by a pair of longer sides 33a and 33b and a pair of shorter sides 34a and 34b, when seen in the thickness direction of the substrate 15a.

The circuit pattern 16a is disposed on the substrate 15a. The circuit pattern 16a is made of, for example, copper. A specific configuration of the circuit pattern 16a will be described in detail later.

The frame member 13 rises from the first surface 12a of the heat dissipation plate 12, and surrounds the substrate 15a when seen in the thickness direction of the substrate 15a. The frame member 13 includes a first wall 13a, a second wall 13b, a third wall 13c, and a fourth wall 13d. The first wall 13a and the second wall 13b are disposed to face each other in the Y direction. The third wall 13c and the fourth wall 13d are disposed to face each other in the X direction. The frame member 13 is made of, for example, an insulative resin. The frame member 13 is fixed to the heat dissipation plate 12 by, for example, an adhesive. The heat dissipation plate 12 and the frame member 13 constitute a case 20 included in the semiconductor device 11a. An inner space 30 of the case 20 is filled with an unillustrated resin filler.

Each of the P-terminal 19a, the O-terminals 19b and 19c, and the N-terminal 19d has a plate shape and is made of a metal. Each of the P-terminal 19a, the O-terminals 19b and 19c, and the N-terminal 19d has a bent band shape. In this embodiment, each of the P-terminal 19a, the O-terminals 19b and 19c, and the N-terminal 19d is formed by bending a band-shaped copper plate. When seen in the thickness direction of the substrate 15a, the P-terminal 19a and the N-terminal 19d are disposed at one side at which the third wall 13c is located with the substrate 15a interposed therebetween, and the O-terminals 19b and 19c are disposed at the other side at which the fourth wall 13d is located with the substrate 15a interposed therebetween. The P-terminal 19a and the N-terminal 19d are disposed at the side opposite to the second shorter side 34b when seen from the first shorter side 34a of the substrate 15a. The O-terminals 19b and 19c are disposed at the side opposite to the first shorter side 34a when seen from the second shorter side 34b. The O-terminals 19b and 19c are attached to the fourth wall 13d. The P-terminal 19a and the N-terminal 19d are attached to the third wall 13c. The semiconductor device 11a obtains electrical connection to the outside by using the P-terminal 19a, the O-terminals 19b and 19c, and the N-terminal 19d. The direction from one side at which the P-terminal 19a and the N-terminal 19d are disposed toward the O-terminals 19b and 19c is represented as a direction indicated by arrow X in FIG. 1. In this embodiment, the first direction is the direction indicated by arrow X or the X direction represented as the opposite direction. Each of the P-terminal 19a, the O-terminals 19b and 19c, and the N-terminal 19d has a position exposed from an inner wall surface 27 of the frame member 13 to the inner space 30 of the case 20. By using this portion, each wire as a connection member is electrically connected.

The first diode chips 21a, 21b, 21c, and 21d, the second diode chips 21e, 21f, 21g, and 21h, the first transistor chips 22a, 22b, 22c, and 22d, and the second transistor chips 22e, 22f, 22g, and 22h have semiconductor layers of SiC or GaN. The first diode chips 21a, 21b, 21c, and 21d and the second diode chips 21e, 21f, 21g, and 21h are, for example, schottky-barrier diodes (SBDs). The first transistor chips 22a, 22b, 22c, and 22d and the second transistor chips 22e, 22f, 22g, and 22h are, for example, metal oxide semiconductor field-effect transistors (MOSFETs).

The first transistor chip 22a is mounted on the circuit pattern 16a. The first transistor chip 22a is electrically coupled to the circuit pattern 16a by the solder portion 18a. The first transistor chip 22a includes a drain electrode located at one end in the thickness direction of the substrate 15a, and a source pad, a gate pad, and a kelvin source pad located at the other end in the thickness direction of the substrate 15a. The first transistor chip 22a is coupled to the circuit pattern 16a such that the drain electrode contacts the circuit pattern 16a by the solder portion 18a. In the first transistor chip 22a, a current flows in the thickness direction of the substrate 15a. The first transistor chip 22a is a vertical transistor chip. The same holds for configurations of the other first transistor chips 22b through 22d and the second transistor chips 22e through 22h.

The first diode chip 21a is mounted on the circuit pattern 16a. In a manner similar to the first transistor chip 22a, the first diode chip 21a is electrically coupled to the circuit pattern 16a by the solder portion. The first diode chip 21a includes a cathode pad located at one end in the thickness direction of the substrate 15a, and an anode pad located at the other end in the thickness direction of the substrate 15a. The first diode chip 21a is coupled to the circuit pattern 16a such that the cathode pad contacts the circuit pattern 16a by the solder portion. In the first diode chip 21a, a current flows in the thickness direction of the substrate 15a. The same holds for configurations of the other first diode chips 21b through 21d and the second diode chips 21e through 21h.

The semiconductor device 11a includes a first gate terminal 41a, a second gate terminal 41b, a first kelvin source terminal 42a, a second kelvin source terminal 42b, a D-terminal 43, and thermistor terminals 44a and 44b. The first gate terminal 41a, the first kelvin source terminal 42a, the D-terminal 43, and the thermistor terminals 44a and 44b are attached to the first wall 13a and are spaced from one another in the X direction.

Specifically, the D-terminal 43, the first kelvin source terminal 42a, the first gate terminal 41a, and the thermistor terminals 44a and 44b are arranged in this order from the side close to the fourth wall 13d. The second gate terminal 41b and the second kelvin source terminal 42b are attached to the second wall 13b. The first gate terminal 41a, the second gate terminal 41b, the first kelvin source terminal 42a, the second kelvin source terminal 42b, the D-terminal 43, and the thermistor terminals 44a and 44b are attached to be partially exposed in the inner space 30. Each of the first gate terminal 41a, the second gate terminal 41b, the first kelvin source terminal 42a, the second kelvin source terminal 42b, the D-terminal 43, and the thermistor terminals 44a and 44b has a portion exposed from the upper surface of the frame member 13 in order to obtain electrical connection to the outside.

A specific configuration of the circuit pattern 16a will now be described. The circuit pattern 16a includes a first region 51a, a second region 52a, a third region 53a, a fourth region 54a, a fifth region 55a, a sixth region 56a, a seventh region 57a, an eighth region 58a, and a ninth region 59a. Each of the first region 51a, the second region 52a, the fourth region 54a, the fifth region 55a, the sixth region 56a, and the seventh region 57a has a band shape and extends in the first direction. The third region 53a includes a first branch portion 61a, a second branch portion 62a, and a connection portion 63a. Each of the first branch portion 61a and the second branch portion 62a has a band shape and extends in the first direction. The connection portion 63a also has a band shape.

The connection portion 63a extends in a second direction that is a width direction pf the first region 51a. In this embodiment, the second direction is the direction indicated by arrow Y or the Y direction represented as the opposite direction. The connection portion 63a connects one end of the first branch portion 61a, which is an end close to the fourth wall 13d in this case, to one end of the second branch portion 62a, which is an end close to the fourth wall 13d. Each of the eighth region 58a and the ninth region 59a has a rectangular shape when seen in the thickness direction of the substrate 15a. The eighth region 58a and the ninth region 59a are disposed side by side with an interval in the X direction when seen in the thickness direction of the substrate 15a. A thermistor 28 included in the semiconductor device 11a is disposed across the eighth region 58a and the ninth region 59a when seen in the thickness direction of the substrate 15a. The thermistor 28 is electrically connected to the eighth region 58a and the ninth region 59a.

The first region 51a, the second region 52a, the fourth region 54a, the fifth region 55a, the sixth region 56a, the seventh region 57a, the first branch portion 61a, and the second branch portion 62a are spaced from one another in the second direction. In this embodiment, in the second direction, the first branch portion 61a is disposed between the first region 51a and the second region 52a. In the second direction, the second region 52a is disposed between the first branch portion 61a and the second branch portion 62a. Specifically, when seen in the thickness direction of the substrate 15a, the fourth region 54a, the fifth region 55a, the first region 51a, the first branch portion 61a, the second region 52a, the second branch portion 62a, the sixth region 56a, and the seventh region 57a are arranged in this order from the side at which the first wall 13a is disposed in the Y direction. A width of each of the fourth region 54a, the fifth region 55a, the sixth region 56a, and the seventh region 57a is smaller than a width of each of the first region 51a and the second region 52a.

In the second direction, a distance between the first wall 13a and the first region 51a is smaller than each of a distance between the first wall 13a and the second region 52a, a distance between the first wall 13a and the first branch portion 61a, and a distance between the first wall 13a and the second branch portion 62a. In the second direction, a distance between the second wall 13b and the second branch portion 62a is smaller than each of a distance between the second wall 13b and the first region 51a, a distance between the second wall 13b and the second region 52a, a distance between the second wall 13b and the first branch portion 61a.

The first diode chips 21a, 21b, 21c, and 21d are disposed on the first region 51a. The first transistor chips 22a, 22b, 22c, and 22d are disposed on the first region 51a. The first diode chips 21a through 21d and the first transistor chips 22a through 22d are spaced from one another in the X direction. The first transistor chip 22a is disposed between the first diode chip 21a and the first diode chip 21b. The first transistor chip 22b is disposed between the first diode chip 21b and the first diode chip 21c. The first transistor chip 22c is disposed between the first diode chip 21c and the first diode chip 21d. The first transistor chip 22d is disposed at the side opposite to the side at which the first transistor chip 22c is disposed with respect to the first diode chip 21d in the X direction. That is, the first transistor chips 22a, 22b, 22c, and 22d and the first diode chips 21a, 21b, 21c, and 21d are alternately arranged along the first direction. An interval between the first transistor chip 22b and the first diode chip 21c in the X direction is larger than an interval between the first transistor chip 22b and the first diode chip 21b in the X direction.

The second diode chips 21e, 21f, 21g, and 21h are disposed on the second branch portion 62a. The second transistor chips 22e, 22f, 22g, and 22h are disposed on the second branch portion 62a. The second diode chip 21e through 21h and the second transistor chip 22e through 22h are spaced from one another in the X direction. The second transistor chip 22e is disposed between the second diode chip 21e and the second diode chip 21f The second transistor chip 22f is disposed between the second diode chip 21f and the second diode chip 21g. The second transistor chip 22g is disposed between the second diode chip 21g and the second diode chip 21h. The second transistor chip 22h is disposed at the side opposite to the side at which the second transistor chip 22g is disposed with respect to the second diode chip 21h in the X direction. That is, the second transistor chips 22e, 22f, 22g, and 22h and the second diode chips 21e, 21f, 21g, and 21h are alternately arranged along the first direction. An interval between the second transistor chip 22f and the second diode chip 21g in the X direction is larger than an interval between the second transistor chip 22f and the second diode chip 21f in the X direction.

The semiconductor device 11a includes first wires electrically connecting the first transistor chips 22a, 22b, 22c, and 22d to the circuit pattern 16a. The first wires include wires 25a, 25b, 25c, and 25d serving as first source wires that are first source connection members electrically connecting the first transistor chips 22a, 22b, 22c, and 22d to the first branch portion 61a. The semiconductor device 11a includes second wires electrically connecting the second transistor chips 22e, 22f, 22g, and 22h to the circuit pattern 16a. The second wires include wires 25e, 25f, 25g, and 25h serving as second source wires that are second source connection members connecting the second transistor chips 22e, 22f, 22g, and 22h to the second region 52a. The semiconductor device 11a includes wires 23a, 23b, 23c, 23d, 24a, 24b, 24c, 24d, 24e, 24f, 24g, 24h, 26a, 26b, 26c, 26d, 26e, 26f, 26g, 31a, 31b, 31c, 31d, 31e, 31f, 31g, 31h, 32a, 32b, 32c, 32d, 32e, 32f, 32g, and 32h serving as connection members.

The P-terminal 19a and the first region 51a are electrically connected to each other by the wire 23a. The O-terminal 19b and the connection portion 63a are electrically connected to each other by the wire 23b. The O-terminal 19c and the connection portion 63a are electrically connected to each other by the wire 23c. The third region 53a including the connection portion 63a is at the same potential as the O-terminals 19b and 19c. The N-terminal 19d and the second region 52a are electrically connected to each other by the wire 23d.

The anode pads of the first diode chips 21a, 21b, 21c, and 21d are electrically connected to the first branch portion 61a by the wires 24a, 24b, 24c, and 24d. The source pads of the first transistor chips 22a, 22b, 22c, and 22d are electrically connected to the first branch portion 61a by the wires 25a, 25b, 25c, and 25d. The gate pads of the first transistor chips 22a, 22b, 22c, and 22d are electrically connected to the fifth region 55a by the wires 31a, 31c, 31e, and 31g. The kelvin source pads of the first transistor chips 22a, 22b, 22c, and 22d are electrically connected to the fourth region 54a by the wires 31b, 31d, 31f, and 31h. The fifth region 55a and the first gate terminal 41a are electrically connected to each other by the wire 26c. The fourth region 54a and the first kelvin source terminal 42a are electrically connected to each other by the wire 26b. Here, the fourth region 54a, the fifth region 55a, the first gate terminal 41a, and the first kelvin source terminal 42a constitute a part of a control circuit for controlling operations of the first transistor chips 22a, 22b, 22c, and 22d. The first region 51a and the D-terminal 43 are electrically connected to each other by the wire 26a. The eighth region 58a and the thermistor terminal 44a are electrically connected to each other by the wire 26d. The ninth region 59a and the thermistor terminal 44b are electrically connected to each other by the wire 26e.

The anode pads of the second diode chips 21e, 21f, 21g, and 21h are electrically connected to the second region 52a by the wires 24e, 24f, 24g, and 24h. The source pads of the second transistor chips 22e, 22f, 22g, and 22h are electrically connected to the second region 52a by the wires 25e, 25f, 25g, and 25h. The gate pads of the second transistor chips 22e, 22f, 22g, and 22h are electrically connected to the sixth region 56a by the wires 32a, 32c, 32e, and 32g. The kelvin source pads of the second transistor chips 22e, 22f, 22g, and 22h are electrically connected to the seventh region 57a by the wires 32b, 32d, 32f, and 32h. The sixth region 56a and the second gate terminal 41b are electrically connected to each other by the wire 26f The seventh region 57a and the second kelvin source terminal 42b are electrically connected to each other by the wire 26g. Here, the sixth region 56a, the seventh region 57a, the second gate terminal 41b, and the second kelvin source terminal 42b constitute a part of a control circuit for controlling operations of the second transistor chips 22e, 22f, 22g, and 22h. The first region 51a and the D-terminal 43 are electrically connected to each other by the wire 26a.

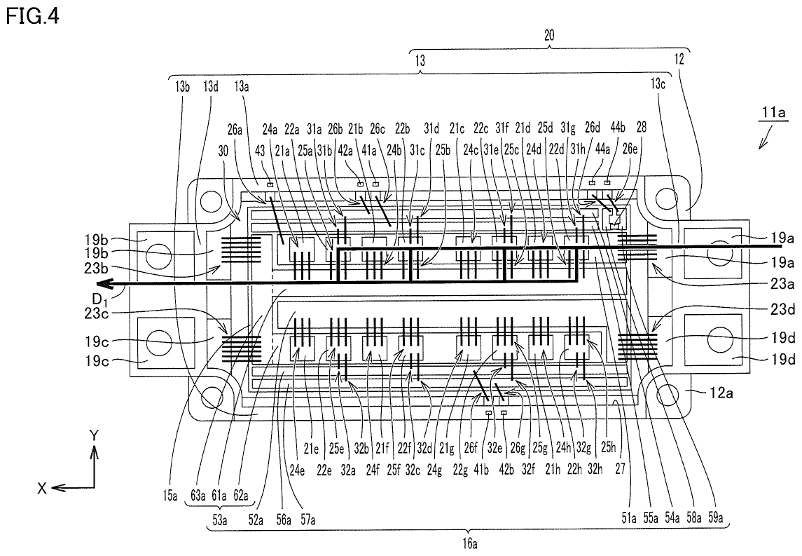

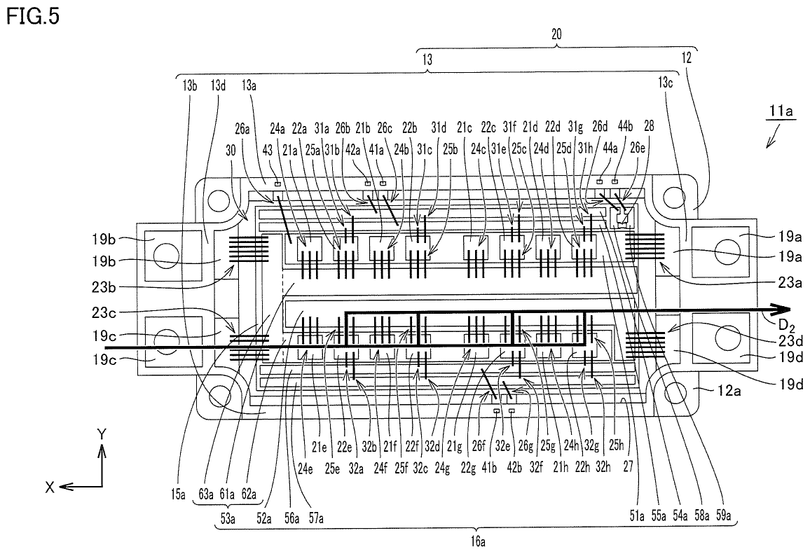

A current flow in the first state will now be described. FIG. 4 is a plan view schematically illustrating a flow of a current in the first state in the semiconductor device 11a according to the first embodiment illustrated in FIG. 1. In FIG. 4, a current flow from the P-terminal 19a to the O-terminal 19b is indicated by arrow D1. FIG. 5 is a plan view schematically illustrating a flow of a current in the second state in the semiconductor device 11 a according to the first embodiment illustrated in FIG. 1. In FIG. 5, a current flow from the O-terminal 19c to the N-terminal 19d is indicated by arrow D2.

First, with reference to FIG. 4, in the first state where the first transistor chips 22a, 22b, 22c, and 22d are on, electrical connection between the P-terminal 19a and the O-terminal 19b is on, and electrical connection between the O-terminal 19c and the N-terminal 19d is off, a current flows from the P-terminal 19a to the O-terminal 19b through the wire 23a, the first region 51a of the circuit pattern 16a, the first transistor chips 22a, 22b, 22c, and 22d in the ON state, the wires 25a, 25b, 25c, and 25d as the first wires, the first branch portion 61a of the third region 53a of the circuit pattern 16a, the connection portion 63a of the third region 53a of the circuit pattern 16a, and then the wire 23b. At this time, no current flows in the second branch portion 62a of the third region 53a of the circuit pattern 16a on which the second transistor chips 22e, 22f, 22g, and 22h in the OFF state are mounted. Then, in the first state, it is possible to suppress inhibition of heat dissipation from the second transistor chips 22e, 22f, 22g, and 22h by heat generation of the second branch portion 62a of the third region 53a of the circuit pattern 16a.

On the other hand, with reference to FIG. 5, in the second state, a current flows from the O-terminal 19c to the N-terminal 19d through the wire 23c, the connection portion 63a of the third region 53a of the circuit pattern 16a, the second branch portion 62a of the third region 53a of the circuit pattern 16a, the second transistor chips 22e, 22f, 22g, and 22h in the ON state, the wires 25e, 25f, 25g, and 25h as the second wires, the second region 52a of the circuit pattern 16a, and then the wire 23d. At this time, no current flows in the first region 51a of the circuit pattern 16a on which the first transistor chips 22a, 22b, 22c, and 22d in the OFF state are mounted. Then, in the second state, it is possible to suppress inhibition of heat dissipation from the first transistor chips 22a, 22b, 22c, and 22d by heat generation of the first region 51a of the circuit pattern 16a.

In the manner described above, the path of a current flowing in the circuit pattern 16a is switched between the first state and the second state. This can reduce a difference between the cooling speed of the first transistor chips 22a, 22b, 22c, and 22d in the OFF state and the cooling speed of the second transistor chips 22e, 22f, 22g, and 22h in the OFF state. Accordingly, the semiconductor device 11a with such a configuration can reduce a temperature difference between the first transistor chips 22a, 22b, 22c, and 22d and the second transistor chips 22e, 22f, 22g, and 22h. As a result, electrical control for obtaining an output close to a desired AC waveform can be facilitated.

In this embodiment, wires serving as a current path between the P-terminal 19a and the O-terminal 19b and wires serving as a current path between the P-terminal 19c and the N-terminal 19d can be easily symmetrized. That is, a wire structure of one region and a wire structure of the other region separated by the chain line in FIG. 1 can be easily symmetrized.

In this embodiment, the semiconductor device 11a includes the heat dissipation plate 12 having the first surface 12a in the thickness direction on which the substrate 15a is mounted, and the frame member 13 rising from the first surface 12a and surrounding the substrate 15a when seen in the thickness direction of the substrate 15a. The outer shape of the substrate 15a is a rectangle whose longer side extends in the first direction when seen in the thickness direction of the substrate 15a. The frame member 13 includes the first wall 13a and the second wall 13b respectively corresponding to the pair of longer sides of the substrate 15a. The P-terminal 19a and the N-terminal 19d are disposed at the side opposite to the second shorter side when seen from the first shorter side of the substrate 15a. The O-terminals 19b and 19c are disposed at the side opposite to the first shorter side when seen from the second shorter side. Thus, the resulting semiconductor device that can easily obtain the configuration of the semiconductor device 11a described above is obtained.

In this embodiment, the semiconductor device 11a includes the first gate terminal 41a attached to the first wall 13a and electrically connected to the gate pads of the first transistor chips 22a, 22b, 22c, and 22d, and the second gate terminal 41b attached to the second wall 13b and electrically connected to the gate pads of the second transistor chips 22e, 22f, 22g, and 22h. In the second direction, a distance between the first wall 13a and the first region 51a is smaller than each of a distance between the first wall 13a and the second region 52a, a distance between the first wall 13a and the first branch portion 61a, and a distance between the first wall 13a and the second branch portion 62a. In the second direction, a distance between the second wall 13b and the second branch portion 62a is smaller than each of a distance between the second wall 13b and the first region 51a, a distance between the second wall 13b and the second region 52a, and a distance between the second wall 13b and the first branch portion 61a. Thus, the semiconductor device 11a can reduce the lengths of the wires 31a, 31c, 31e, and 31g as the wires connecting the first gate terminal 41a to the gate pads of the first transistor chips 22a, 22b, 22c, and 22d and the lengths of the wires 32a, 32c, 32e, and 32g as wires connecting the second gate terminal 41b to the gate pads of the second transistor chips 22e, 22f, 22g, and 22h. Accordingly, inductance can be reduced.

The semiconductor device 11a include the first kelvin source terminal 42a attached to the first wall 13a and electrically connected to the kelvin source pads of the first transistor chips 22a, 22b, 22c, and 22d, and the second kelvin source terminal 42b attached to the second wall 13b and electrically connected to the kelvin source pads of the second transistor chips 22e, 22f, 22g, and 22h. In the second direction, a distance between the first wall 13a and the first region 51a is smaller than each of a distance between the first wall 13a and the second region 52a, a distance between the first wall 13a and the first branch portion 61a, and a distance between the first wall 13a and the second branch portion 62a. In the second direction, a distance between the second wall 13b and the second branch portion 62a is smaller than each of a distance between the second wall 13b and the first region 51a, a distance between the second wall 13b and the second region 52a, and a distance between the second wall 13b and the first branch portion 61a. With this configuration, the semiconductor device 11a can reduce the lengths of the wires 31b, 31d, 31f, and 31h as wires connecting the first kelvin source terminal 42a to the kelvin source pads of the first transistor chips 22a, 22b, 22c, and 22d and the lengths of the wires 32b, 32d, 32f, and 32h as wires connecting the second kelvin source terminal 42b to the kelvin source pads of the second transistor chips 22e, 22f, 22g, and 22h. Accordingly, inductance can be reduced.

In this embodiment, the semiconductor device 11a includes the wires 25a, 25b, 25c, and 25d as first source wires electrically connecting the source pads of the first transistor chips 22a, 22b, 22c, and 22d to the first branch portion 61a, and the wires 25e, 25f, 25g, and 25h as second source wires electrically connecting the source pads of the second transistor chips 22e, 22f, 22g, and 22h to the second region 52a. The lengths of the wires 25a, 25b, 25c, and 25d are equal to the lengths of the wires 25e, 25f, 25g, and 25h. The number of the wires 25a, 25b, 25c, and 25d is equal to the number of the wires 25e, 25f, 25g, and 25h. Thus, with this semiconductor device 11a, the value of inductance in electrical paths can be easily made uniform. Accordingly, electrical characteristics of the paths can be easily made uniform so that electrical control can be facilitated.

In this embodiment, at least one of the first transistor chips 22a, 22b, 22c, and 22d or the second transistor chips 22e, 22f, 22g, and 22h include semiconductor layers of SiC or GaN. The transistor chip including such a semiconductor layer can switch at high speed, and thus, is preferable for the semiconductor device according to the present disclosure that switches current paths.

In this embodiment, the first gate terminal 41a and the first kelvin source terminal 42a are adjacent to each other and attached to the first wall 13a. The second gate terminal 41b and the second kelvin source terminal 42b are adjacent to each other and attached to the second wall 13b. The circuit pattern 16a includes the band-shaped fourth region 54a electrically connected to the first kelvin source terminal 42a by the wire 26b, spaced from the first region 51a in the second direction, and extending along the first direction, the band-shaped fifth region 55a electrically connected to the first gate terminal 41a by the wire 26c, spaced from the fourth region 54a in the second direction, and extending along the first direction, the band-shaped sixth region 56a electrically connected to the second gate terminal 41b by the wire 26f, spaced from the second branch portion 62a in the second direction, and extending along the first direction, and the band-shaped seventh region 57a electrically connected to the second kelvin source terminal 42b by the wire 26g, spaced from the sixth region 56a in the second direction, and extending along the first direction.

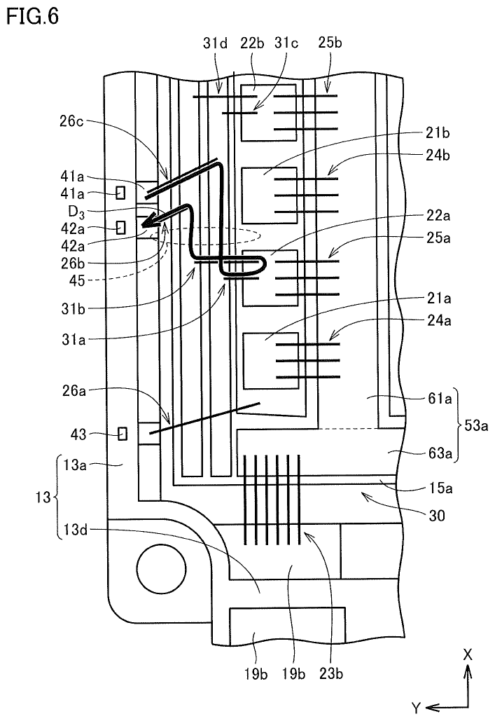

FIG. 6 is an enlarged view of a part of the semiconductor device 11a illustrated in FIG. 1. With reference to FIG. 6, the direction of a current flowing from the first gate terminal 41a to the gate pads of the first transistor chips 22a, 22b, 22c, and 22d in the fifth region 55a is opposite to the direction of a current flowing from the kelvin source pads of the first transistor chips 22a, 22b, 22c, and 22d to the first kelvin source terminal 42a in the fourth region 54a. With reference to FIG. 1, for example, the direction of a current flowing from the second gate terminal 41b to the gate pads of the second transistor chips 22e, 22f, 22g, and 22h in the sixth region 56a is opposite to the direction of a current flowing from the kelvin source pads of the second transistor chips 22e, 22f, 22g, and 22h to the second kelvin source terminal 42b in the seventh region 57a. With this configuration, while a current flows in a current path indicated by arrow D3 and constituted by the first gate terminal 41a, the fifth region 55a of the circuit pattern 16a, the first transistor chip 22a, the fourth region 54a of the circuit pattern 16a, and the first kelvin source terminal 42a, the direction of the current flowing between the fourth region 54a and the fifth region 55a spaced from each other in the second direction can be reversed in the region 45 indicated by, for example, a broken line. Similarly, although the current path is not shown, while a current flows in the current path constituted by the second gate terminal 41b, the seventh region 57a of the circuit pattern 16a, the second transistor chip 22e, the sixth region 56a of the circuit pattern 16a, and the second kelvin source terminal 42b, the direction of a current flowing can be reversed between the sixth region 56a and the seventh region 57a spaced from each other in the second direction. Thus, inductance of these control circuits can be reduced by mutual inductance.

### SECOND EMBODIMENT

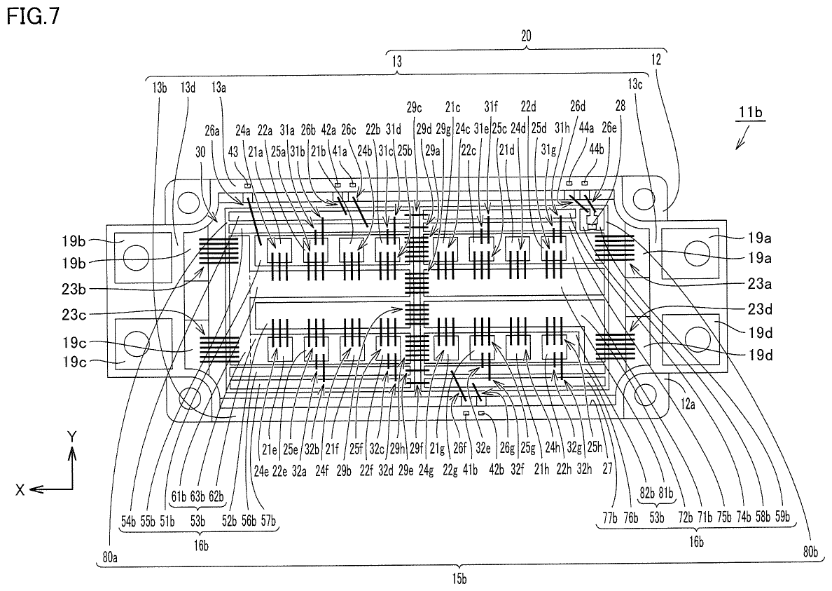

A second embodiment as another embodiment will now be described. FIG. 7 is a schematic plan view of the semiconductor device according to the second embodiment when seen in the thickness direction of a substrate. The semiconductor device according to the second embodiment is different from that of the first embodiment in that a substrate and a circuit pattern are divided.

With reference to FIG. 7, a substrate 15b included in a semiconductor device 11b according to the second embodiment is divided into a first substrate 80a and a second substrate 80b. The outer shape of each of the first substrate 80a and the second substrate 80b is a rectangle when seen in the thickness direction of the substrate 15b. The first substrate 80a and the second substrate 80b are disposed side by side with an interval in the X direction. The semiconductor device 11b according to the second embodiment includes wires 29a, 29b, 29c, 29d, 29e, 29f, 29g, and 29h as connection members.

In the second embodiment, a part of a circuit pattern 16b disposed on the substrate 15b is also divided. Specifically, the circuit pattern 16b includes first regions 51b and 71b, second regions 52b and 72b, a third region 53b, fourth regions 54b and 74b, fifth regions 55b and 75b, sixth regions 56b and 76b, seventh region 57b, 77b, an eighth region 58b, and a ninth region 59b. Configurations of the eighth region 58b and the ninth region 59b are similar to those of the eighth region 58a and the ninth region 59a, and thus, will not be described. The third region 53b includes first branch portions 61b and 81b, second branch portions 62b and 82b, and a connection portion 63b. On the first substrate 80a, the first region 51b, the second region 52b, the fourth region 54b, the fifth region 55b, the sixth region 56b, the seventh region 57b, the first branch portion 61b, the second branch portion 62b, and the connection portion 63b are disposed. On the second substrate 80b, the first region 71b, the second region 72b, the fourth region 74b, the fifth region 75b, the sixth region 76b, the seventh region 77b, the eighth region 58b, and the ninth region 59b are disposed.

The first regions 51b and 71b are divided into the one-side first region 51b disposed at one side in a first direction and the other-side first region 71b disposed at the other side in the first direction, and the one-side first region 51b and the other-side first region 71b are disposed side by side along the first direction. The second regions 52b and 72b are divided into the one-side second region 52b disposed at one side in the first direction and the other-side second region 72b disposed at the other side in the first direction, and one-side second region 52b and the other-side second region 72b are disposed side by side along the first direction. The first branch portions 61b and 81b are divided into the one-side first branch portion 61b disposed at one side in the first direction and the other-side first branch portion 81b disposed at the other side, and the one-side first branch portion 61b and the other-side first branch portion 81b are disposed side by side along the first direction. The second branch portions 62b and 82b are divided into the one-side second branch portion 62b disposed at one side in the first direction and the other-side second branch portion 82b disposed at the other side, and the one-side second branch portion 62b and the other-side second branch portion 82b are disposed side by side along the first direction. Each of the one-side first region 51b, the one-side second region 52b, the one-side first branch portion 61b, and the one-side second branch portion 62b is disposed near O-terminals 19b and 19c in the first direction. Each of the other-side first region 71b, the other-side second region 72b, the other-side first branch portion 81b, and the other-side second branch portion 82b is disposed near a P-terminal 19a and an N-terminal 19d in the first direction.

The width of the one-side first region 51b, that is, the length of the one-side first region 51b in the second direction, is equal to the width of the other-side first region 71b, that is, the length of the other-side first region 71b in the second direction. The width of the one-side second region 52b, that is, the length of the one-side second region 52b in the second direction, is equal to the width of the other-side second region 72b, that is, the length of the other-side second region 72b in the second direction. The width of the one-side first branch portion 61b, that is, the length of one-side first branch portion 61b in the second direction, is equal to the width of the other-side first branch portion 81b, that is, the length of the other -side first branch portion 81b in the second direction. The width of the one-side second branch portion 62b, that is, the length of the one-side second branch portion 62b in the second direction, is equal to the width of the other-side second branch portion 82b, that is, the length of the other-side second branch portion 82b in the second direction.

First diode chips 21a and 21b and first transistor chips 22a and 22b are mounted on the one-side first region 51b. First diode chips 21c and 21d and first transistor chips 22c and 22d are mounted on the other-side first region 71b. Second diode chips 21e and 21f and second transistor chips 22e and 22f are mounted on the one-side second branch portion 62b. Second diode chips 21g and 21h and second transistor chips 22g and 22h are mounted on the other-side second branch portion 82b. The order of arrangement of the first direction is similar to that in the first embodiment.

The divided portions are electrically connected to one another by wires. Specifically, the first region 51b on the first substrate 80a and the first region 71b on the second substrate 80b are electrically connected to each other by the wire 29a. The second region 52b on the first substrate 80a and the second region 72b on the second substrate 80b are electrically connected to each other by the wire 29b. The fourth region 54b on the first substrate 80a and the fourth region 74b on the second substrate 80b are electrically connected to each other by the wire 29c. The fifth region 55b on the first substrate 80a and the fifth region 75b on the second substrate 80b are electrically connected to each other by the wire 29d. The sixth region 56b on the first substrate 80a and the sixth region 76b on the second substrate 80b are electrically connected to each other by the wire 29e. The seventh region 57b on the first substrate 80a and the seventh region 77b on the second substrate 80b are electrically connected to each other by the wire 29f The first branch portion 61b on the first substrate 80a and the first branch portion 81b on the second substrate 80b are electrically connected to each other by the wire 29g. The second branch portion 62b on the first substrate 80a and the second branch portion 82b on the second substrate 80b are electrically connected to each other by the wire 29h.

In the manner described above, even in the case where the substrate 15b and the circuit pattern 16b on the substrate 15b are divided, it is sufficient that divided portions thereof are electrically connected to each other. With this configuration, electrical control for obtaining an output close to a desired AC waveform can also be facilitated. In this embodiment, each pair of the first regions 51b and 71b, the second regions 52b and 72b, the first branch portions 61b and 81b, and the second branch portions 62b and 82b is divided in the first direction so that the divided portions are disposed on the different substrates 80a and 80b. Accordingly, stress occurring based on a difference between thermal expansion coefficients of members can be reduced.

### THIRD EMBODIMENT

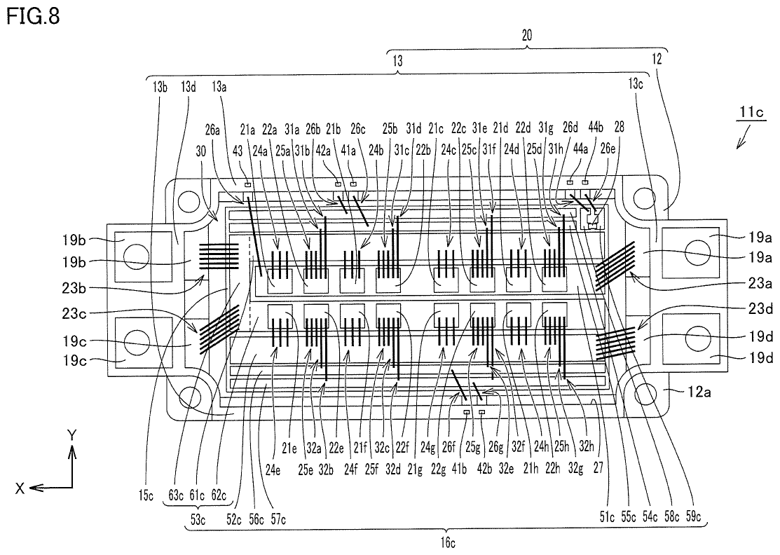

A third embodiment as another embodiment will now be described. FIG. 8 is a schematic plan view of the semiconductor device according to the third embodiment when seen in the thickness direction of a substrate. The semiconductor device according to the third embodiment is different from the first embodiment in arrangement of the circuit pattern mounted on the substrate.

With reference to FIG. 8, a semiconductor device 11c according to the third embodiment includes a substrate 15c, and a circuit pattern 16c mounted on the substrate 15c. The circuit pattern 16c disposed on the substrate 15c includes a first region 51c, a second region 52c, a third region 53c, a fourth region 54c, a fifth region 55c, a sixth region 56c, a seventh region 57c, an eighth region 58c, and a ninth region 59c.

Configurations of the eighth region 58c and the ninth region 59c are similar to those of the eighth region 58a and the ninth region 59a, and thus, will not be described. The third region 53c includes a first branch portion 61c, a second branch portion 62c, and a connection portion 63c.

In this embodiment, in the second direction, the second branch portion 62c is disposed between the first region 51c and the second region 52c. In the second direction, the first region 51c is disposed between the first branch portion 61c and the second branch portion 62c. Specifically, when seen in the thickness direction of the substrate 15a, the fourth region 54c, the fifth region 55c, the first branch portion 61c, the first region 51c, the second branch portion 62c, the second region 52c, the sixth region 56c, and the seventh region 57c are arranged in this order from the side at which the first wall 13a is disposed in the Y direction.

With this configuration, electrical control for obtaining an output close to a desired AC waveform can also be facilitated. In this embodiment, when seen in the thickness direction of the substrate 15a, the first transistor chips 22a through 22d and the second transistor chips 22e through 22h can be arranged in a region close to the center of the heat dissipation plate 12, and thus, heat dissipation can be enhanced.

### FOURTH EMBODIMENT

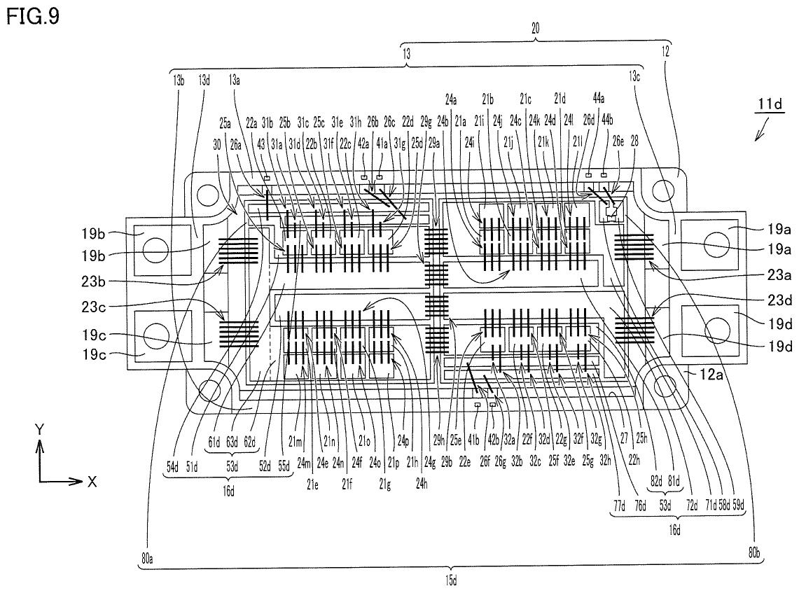

A fourth embodiment as another embodiment will now be described. FIG. 9 is a schematic plan view of the semiconductor device according to the fourth embodiment when seen in the thickness direction of a substrate. The semiconductor device according to the fourth embodiment is different from the first embodiment in arrangement of the circuit pattern mounted on the substrate.

With reference to FIG. 9, in a manner similar to the substrate 15b described in the second embodiment, a substrate 15d included in a semiconductor device 11d according to the fourth embodiment is divided into a first substrate 80a and a second substrate 80b. The outer shape of each of the first substrate 80a and the second substrate 80b is a rectangle when seen in the thickness direction of the substrate 15d. The first substrate 80a and the second substrate 80b are disposed side by side with an interval in the X direction.

In the fourth embodiment, a part of a circuit pattern 16d disposed on the substrate 15d is also divided. Specifically, the circuit pattern 16d includes first regions 51d and 71d, second regions 52d and 72d, a third region 53d, a fourth region 54d, a fifth region 55d, a sixth region 76d, a seventh region 77d, an eighth region 58d, and a ninth region 59d. Configurations of the eighth region 58d and the ninth region 59d are similar to those of the eighth region 58a and the ninth region 59a, and thus, will not be described. The third region 53d includes first branch portions 61d and 81d, second branch portions 62d, and 82d, and a connection portion 63d. On the first substrate 80a, the first region 51d, the second region 52d, the fourth region 54d, the fifth region 55d, the first branch portion 61d, the second branch portion 62d, and the connection portion 63d are disposed.

That is, in this embodiment, unlike the second embodiment, the sixth region 76d and the seventh region 77d are not disposed on the first substrate 80a. On the second substrate 80b, the first region 71d, the second region 72d, the sixth region 76d, the seventh region 77d, the eighth region 58d, and the ninth region 59d are disposed. That is, in this embodiment, unlike the second embodiment, the fourth region 54d and the fifth region 55d are not disposed on the second substrate 80b.

The first regions 51d and 71d are divided into the one-side first region 51d disposed at one side in the first direction and the other-side first region 71d disposed at the other side in the first direction, and the one-side first region 51d and the other-side first region 71d are disposed side by side along the first direction. In the second direction, the fourth region 54d and the fifth region 55d are disposed adjacent to the one-side first region 51d. The second regions 52d and 72d are divided into the one-side second region 52d disposed at one side and the other-side second region 72d disposed at the other side in the first direction, and the one-side second region 52d and the other-side second region 72d are disposed side by side along the first direction. The first branch portions 61d and 81d are divided into the one-side first branch portion 61d disposed at one side and the other-side first branch portion 81d disposed at the other side in the first direction, and the one-side first branch portion 61d and the other-side first branch portion 81d are disposed side by side along the first direction. The second branch portions 62d and 82d are divided into the one-side second branch portion 62d disposed at one side and the other-side second branch portion 82d disposed at the other side in the first direction, and the one-side second branch portion 62d and the other-side second branch portion 82d are disposed side by side along the first direction. In the second direction, the sixth region 76d and the seventh region 77d are disposed adjacent to the other-side second branch portion 82d. Each of the one-side first region 51d, the one-side second region 52d, the one-side first branch portion 61d, and the one-side second branch portion 62d is disposed near O-terminals 19b and 19c in the first direction. Each of the other-side first region 71d, the other-side second region 72d, the other-side first branch portion 81d, and the other-side second branch portion 82d is disposed near a P-terminal 19a and an N-terminal 19d in the first direction.

The width of the one-side first region 51d, that is, the length of the one-side first region 51d in the second direction, is equal to the width of the other-side first region 71d, that is, the length of the other-side first region 71d in the second direction. The length of the other-side first region 71d in the second direction is long enough to dispose two diode chips side by side in the second direction. The width of the one-side second region 52d, that is, the length of the one-side second region 52d in the second direction, is equal to the width of the other-side second region 72d, that is, the length of the other-side second region 72d in the second direction. The width of the one-side first branch portion 61d, that is, the length of the one-side first branch portion 61d in the second direction, is equal to the width of the other-side first branch portion 81d, that is, the length of the other-side first branch portion 81d in the second direction. The width of the one-side second branch portion 62d, that is, the length of the one-side second branch portion 62d in the second direction, is equal to the width of the other-side second branch portion 82d, that is, the length of the other-side second branch portion 82d in the second direction. The one-side second branch portion 62d has a length enough to dispose two diode chips side by side in the second direction.

The divided portions are electrically connected by wires as connection members. Specifically, the first region 51d on the first substrate 80a and the first region 71d on the second substrate 80b are electrically connected to each other by the wire 29a. The second region 52d on the first substrate 80a and the second region 72d on the second substrate 80b are electrically connected to each other by the wire 29b. The first branch portion 61d on the first substrate 80a and the first branch portion 81d on the second substrate 80b are electrically connected to each other by the wire 29g. The second branch portion 62d on the first substrate 80a and the second branch portion 82d on the second substrate 80b are electrically connected to each other by the wire 29h.

The first transistor chips 22a, 22b, 22c, and 22d are mounted on the one-side first region 51d. The first transistor chips 22a, 22b, 22c, and 22d are adjacent to one another along the first direction. The first diode chips 21a, 21b, 21c, and 21d are mounted on the other-side first region 71d. The first diode chips 21a, 21b, 21c, and 21d are adjacent to one another along the first direction. Locations of the first transistor chips 22a, 22b, 22c, and 22d in the second direction are the same as locations of the first diode chips 21a, 21b, 21c, and 21d in the second direction. The second transistor chips 22e, 22f, 22g, and 22h are mounted on the other-side second branch portion 82d. The second transistor chips 22e, 22f, 22g, and 22h are adjacent to one another along the first direction. The second diode chips 21e, 21f, 21g, and 21h are mounted on the one-side second branch portion 62d. The second diode chips 21e, 21f, 21g, and 21h are adjacent to one another along the first direction. Locations of the second transistor chips 22e, 22f, 22g, and 22h in the second direction are the same as locations of the second diode chips 21e, 21f, 21g, and 21h in the second direction.

With this configuration, the plurality of first transistor chips 22a, 22b, 22c, and 22d are concentrated so that inductance of a gate loop in each of the plurality of first transistor chips 22a, 22b, 22c, and 22d can be reduced. In addition, a difference in gate loop inductance between the second transistor chips 22a, 22b, 22c, and 22d can also be reduced. Similarly, inductance of the gate loop in each of the plurality of the second transistor chips 22e, 22f, 22g, and 22h can be reduced. A difference in gate loop inductance between the second transistor chips 22e, 22f, 22g, and 22h can also be reduced. Accordingly, high-speed operation can be further stabilized. In addition, with this configuration, the plurality of first transistor chips 22a, 22b, 22c, and 22d can be concentrated and routing of wires in a control circuit for controlling operation of the plurality of first transistor chips 22a, 22b, 22c, and 22d can be facilitated so that the control circuit for controlling the plurality of first transistor chips 22a, 22b, 22c, and 22d occupies a compact region. Then, a large region can be obtained for arrangement of the plurality of first diode chips 21a, 21b, 21c, and 21d in the second direction without an increase in the entire size so that a large number of the first diode chips 21a, 21b, 21c, and 21d can be disposed. The same holds for the plurality of second transistor chips 22e, 22f, 22g, and 22h and the plurality of second diode chips 21e, 21f, 21g, and 21h. Thus, design flexibility increases, and improvement of heat dissipation and reduction of parasitic inductance can be taken into consideration.

The semiconductor device 11d according to the fourth embodiment further includes a plurality of third diode chips 21i, 21j, 21k, and 21l and a plurality of fourth diode chips 21m, 21n, 21o, and 21p mounted on the circuit pattern. Configurations of the plurality of third diode chips 21i, 21j, 21k, and 21l and the plurality of fourth diode chips 21m, 21n, 21o, and 21p are similar to that of the first diode chip 21a, and will not be described.

The third diode chips 21i, 21j, 21k, and 21l are adjacent to one another along the first direction, and are disposed side by side with the first diode chips 21a, 21b, 21c, and 21d along the second direction. Specifically, when seen in the thickness direction of the substrate 15d, in the second direction, each of the third diode chips 21i, 21j, 21k, and 21l is disposed between a corresponding one of the first diode chips 21a, 21b, 21c, and 21d and the first wall 13a. The third diode chips 21i, 21j, 21k, and 21l are mounted on the first region 71d to be electrically connected to the first region 71d, and are electrically connected to the first branch portion 81d by connection members. Specifically, anode pads of the third diode chips 21i, 21j, 21k, and 21l are connected to anode pads of the first diode chips 21a, 21b, 21c, and 21d by wires 24i, 24j, 24k, and 24l as connection members. That is, the third diode chips 21i, 21j, 21k, and 21l are electrically connected to the first branch portion 81d through the first diode chips 21a, 21b, 21c, and 21d.

The fourth diode chips 21m, 21n, 21o, and 21p are adjacent to one another along the first direction, and are disposed side by side with the second diode chips 21e, 21f, 21g, and 21h along the second direction. Specifically, when seen in the thickness direction of the substrate 15d, in the second direction, each of the fourth diode chips 21m, 21n, 21o, and 21p is disposed between a corresponding one of the second diode chips 21e, 21f, 21g, and 21h and the second wall 13b. The fourth diode chips 21m, 21n, 21o, and 21p are mounted on the second branch portion 62d to be electrically connected to the second branch portion 62d, and electrically connected to the second region 52d by connection members. Specifically, anode pads of the fourth diode chips 21m, 21n, 21o, and 21p are connected to anode pads of the second diode chips 21e, 21f, 21g, and 21h by wires 24m, 24n, 24o, and 24p as connection members. That is, the fourth diode chips 21m, 21n, 21o, and 21p are electrically connected to the second region 52d through the second diode chips 21e, 21f, 21g, and 21h.

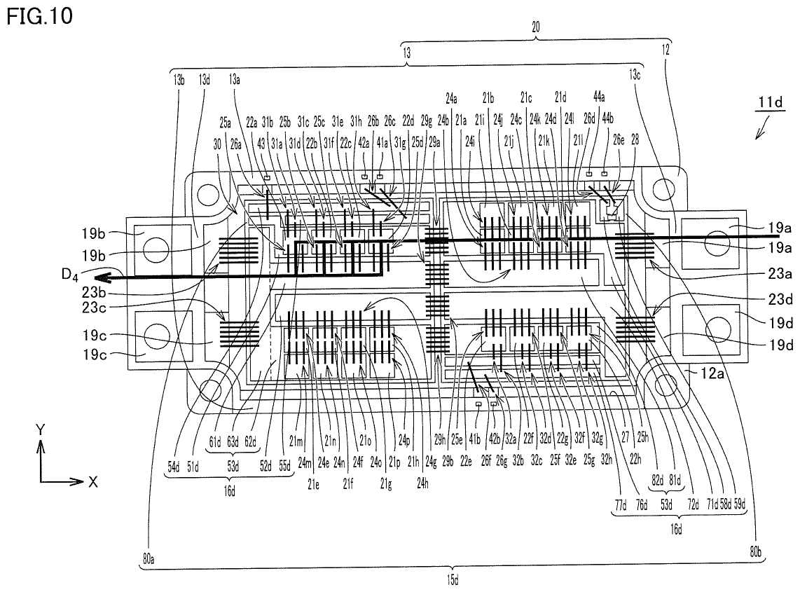

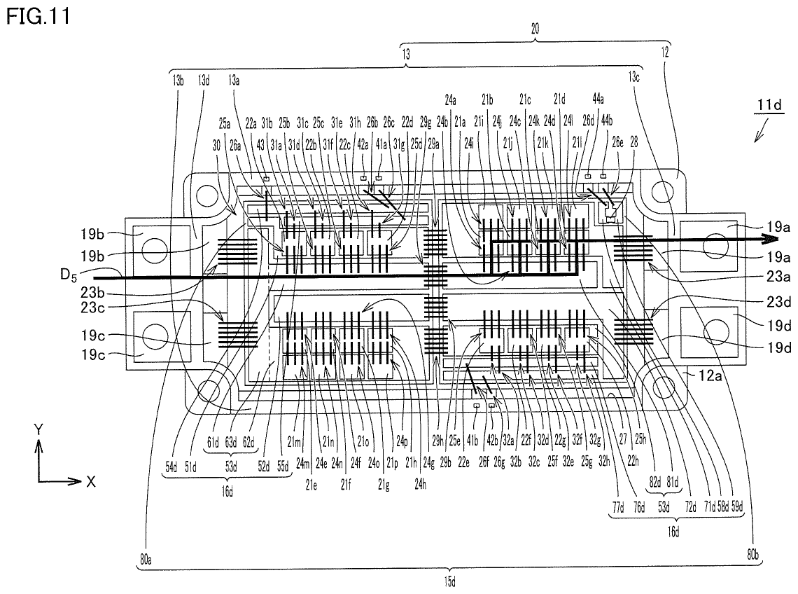

FIG. 10 is a plan view schematically illustrating a current flow in a forward direction, that is, from the P-terminal 19a to the O-terminal 19b, in the semiconductor device 11d according to the fourth embodiment illustrated in FIG. 9. In FIG. 10, a current flow from the P-terminal 19a to the O-terminal 19b is indicated by arrow D4. FIG. 11 is a plan view schematically illustrating a flow of a current in a reverse direction, that is, from the O-terminal 19b to the P-terminal 19a, in the semiconductor device 11d according to the fourth embodiment illustrated in FIG. 9. In FIG. 11, a current flow from the O-terminal 19b to the P-terminal 19a is indicated by arrow D5.

First, with reference to FIG. 10, while a current flows from the P-terminal 19a toward the O-terminal 19b in the forward direction as indicated by arrow D4, the current flows from the P-terminal 19a to the O-terminal 19b through the wire 23a, the first region 71d (the other-side first region) of the circuit pattern 16d, the wire 29a, the first region 51d (the one-side first region) of the circuit pattern 16d, the first transistor chips 22a, 22b, 22c, and 22d, the wires 25a, 25b, 25c, and 25d as the first wires, the first branch portion 61d (the one-side first branch portion) of the third region 53d of the circuit pattern 16a, the connection portion 63d of the third region 53d of the circuit pattern 16a, and then the wire 23b.

Next, with reference to FIG. 11, while a current flows from the O-terminal 19b toward the P-terminal 19a in the reverse direction as indicated by arrow D5, the current flows from the O-terminal 19b to the P-terminal 19a through the wire 23b, the connection portion 63d of the third region 53d of the circuit pattern 16a, the first branch portion 61d (the one-side first branch portion) of the third region 53d of the circuit pattern 16a, the wire 29g, the first branch portion 81d (the other-side first branch portion) of the third region 53d of the circuit pattern 16a, the wires 24a, 24b, 24c, and 24d, the first diode chips 21a, 21b, 21c, and 21d, the first region 71d (the other-side first region) of the circuit pattern 16d, and then the wire 23a. In another path, a current flows from the wires 24a, 24b, 24c, and 24d to the P-terminal 19a through the wires 24i, 24j, 24k, and 24l, the third diode chips 21i, 21j, 21k, and 21l, the first region 71d (the other-side first region) of the circuit pattern 16d, and then the wire 23a. The same holds for a path in which a current flows through the second transistor chips 22e, 22f, 22g, and 22h, the second diode chips 21e, 21f, 21g, and 21h, and the fourth diode chips 21m, 21n, 21o, and 21p.

In this embodiment, a path of a current flowing in the first transistor chips 22a, 22b, 22c, and 22d and a path of a current flowing in the first diode chips 21a, 21b, 21c, and 21d and the third diode chips 21i, 21j, 21k, and 21l can be distinctly separated. A path of a current flowing in the second transistor chips 22e, 22f, 22g, and 22h and a path of a current flowing in the second diode chips 21e, 21f, 21g, and 21h and the fourth diode chips 21m, 21n, 21o, and 21p can be distinctly separated. Thus, heat generation of the wires 29a, 29b, 29g, and 29h connecting divided portions is suppressed so that the risk of fusing of the wires 29a, 29b, 29g, and 29h can be reduced. The divided portions may be connected not only by wires but also by ribbon wires or bus bars.

In this embodiment, a current is allowed to flow in the plurality of third diode chips 21i, 21j, 21k, and 21l in addition to the plurality of first diode chips 21a, 21b, 21c, and 21d. A current is allowed to flow in the plurality of fourth diode chips 21m, 21n, 21o, and 21p in addition to the plurality of second diode chips 21e, 21f, 21g, and 21h. Accordingly, the amount of a current flowing in each diode chip can be reduced. As a result, the amount of heat generation in each diode chip can be reduced so that the possibility of deterioration can be reduced.

In this embodiment, in the other-side first region 71d, a current is allowed to flow in the plurality of third diode chips 21i, 21j, 21k, and 21l in addition to the plurality of first diode chips 21a, 21b, 21c, and 21d. In this case, a path of a current flowing in the third diode chips 21i, 21j, 21k, and 21l and a path of a current flowing in the first transistor chips 22a, 22b, 22c, and 22d can be separated. In the one-side second branch portion 62d, a current is allowed to flow in the plurality of fourth diode chips 21m, 21n, 21o, and 21p in addition to the plurality of second diode chips 21e, 21f, 21g, and 21h. In this case, a path of a current flowing in the fourth diode chips 21m, 21n, 21o, and 21p and a path of a current flowing in the second transistor chips 22e, 22f, 22g, and 22h can be separated. Accordingly, the amount of heat generation in the diode chips can be efficiently reduced.

### FIFTH EMBODIMENT

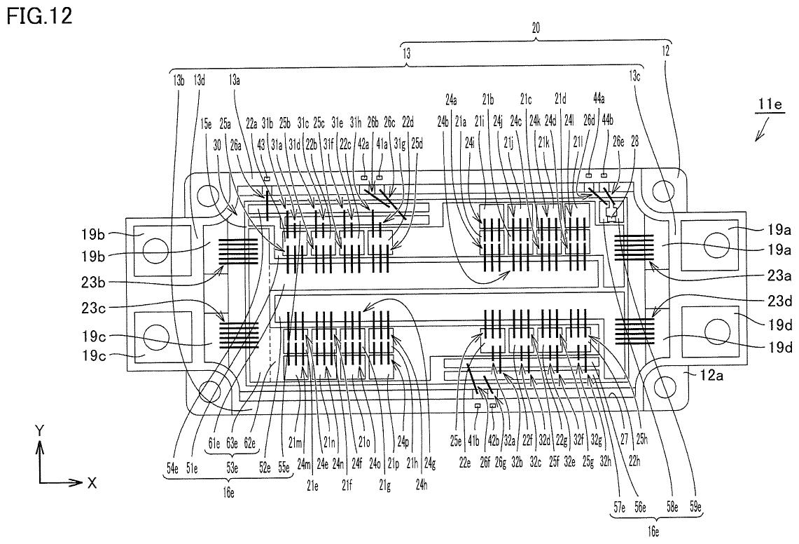

A fourth embodiment as another embodiment will now be described. FIG. 12 is a schematic plan view of a semiconductor device according to the fifth embodiment when seen in the thickness direction of a substrate. The semiconductor device according to the fifth embodiment is different from that of the fourth embodiment in that none of a substrate, a first region, a second region, a first branch portion, and a second branch portion is divided.

With reference to FIG. 12, a substrate 15e included in a semiconductor device 11e according to the fifth embodiment is not divided in a first direction unlike the fourth embodiment, and is constituted by one substrate in the same manner as the first embodiment. A circuit pattern 16e includes a first region 51e, a second region 52e, a third region 53e, a fourth region 54e, a fifth region 55e, a sixth region 56e, a seventh region 57e, an eighth region 58e, and a ninth region 59e. The third region 53e includes a first branch portion 61e, a second branch portion 62e, and a connection portion 63e. Configurations of the fourth region 54e, the fifth region 55e, the sixth region 56e, the seventh region 57e, the eighth region 58e, the ninth region 59e, and the connection portion 63e are similar to those of the fourth region 54d, the fifth region 55d, the sixth region 76d, the seventh region 77d, the eighth region 58d, the ninth region 59d, and the connection portion 63d, and will not be described. Each of the first region 51e, the second region 52e, the first branch portion 61e, and the second branch portion 62e is not divided in the first direction unlike the fourth embodiment, and extends along the first direction. That is, the fifth embodiment employs the configuration in which each of the first region 51e, the second region 52e, the first branch portion 61e, and the second branch portion 62e is not divided in the first direction in the same manner as the first embodiment.

A plurality of first transistor chips 22a, 22b, 22c, and 22d, a plurality of first diode chips 21a, 21b, 21c, and 21d, and a plurality of third diode chips 21i, 21j, 21k, and 21l are mounted on the first region 51e. The plurality of first transistor chips 22a, 22b, 22c, and 22d are adjacent to one another along the first direction. The plurality of first diode chips 21a, 21b, 21c, and 21d are adjacent to one another along the first direction. The first transistor chips 22a, 22b, 22c, and 22d are disposed together near an O-terminal 19b, and the first diode chips 21a, 21b, 21c, and 21d are disposed together near a P-terminal 19a. In this embodiment, the first transistor chips 22a, 22b, 22c, and 22d are disposed closer to the O-terminal 19b than the center in the first direction, and the first diode chips 21a, 21b, 21c, and 21d are disposed closer to the P-terminal 19a than the center in the first direction. The plurality of third diode chips 21i, 21j, 21k, and 21l are also adjacent to one another along the first direction. The third diode chips 21i, 21j, 21k, and 21l are disposed together closer to the P-terminal 19a than the center in the first direction. The plurality of first diode chips 21a, 21b, 21c, and 21d and the plurality of third diode chips 21i, 21j, 21k, and 21l are spaced from one another in the second direction. Locations of the plurality of first diode chips 21a, 21b, 21c, and 21d in the first direction are the same as locations of the third diode chips 21i, 21j, 21k, and 21l in the first direction.

The plurality of second transistor chips 22e, 22f, 22g, and 22h, the plurality of second diode chips 21e, 21f, 21g, and 21h, and the plurality of fourth diode chips 21m, 21n, 21o, and 21p are mounted on the second branch portion 62e. The plurality of second transistor chips 22e, 22f, 22g, and 22h are adjacent to one another along the first direction. The plurality of second diode chips 21e, 21f, 21g, and 21h are adjacent to one another along the first direction. The second transistor chips 22e, 22f, 22g, and 22h are disposed together near an N-terminal 19d, and the second diode chips 21e, 21f, 21g, and 21h are disposed together near an O-terminal 19c. In this embodiment, the second transistor chips 22e, 22f, 22g, and 22h are disposed closer to the N-terminal 19d than the center in the first direction, and the second diode chips 21e, 21f, 21g, and 21h are disposed closer to the O-terminal 19c than the center in the first direction. The plurality of fourth diode chips 21m, 21n, 21o, and 21p are also adjacent to one another along the first direction. The fourth diode chips 21m, 21n, 21o, and 21p are also disposed together closer to the O-terminal 19c than the center in the first direction. The plurality of second diode chips 21e, 21f, 21g, and 21h and the plurality of fourth diode chips 21m, 21n, 21o, and 21p are spaced from one another in the second direction. Locations of the plurality of second diode chips 21e, 21f, 21g, and 21h in the first direction are the same as locations of the fourth diode chips 21m, 21n, 21o, and 21p in the first direction.

With this configuration, electrical control for obtaining an output close to a desired AC waveform can also be facilitated. In this embodiment, wires connecting divided portions can be omitted so that the risk of fusing of the wires can be reduced, as compared to the case described in the fourth embodiment.

### OTHER EMBODIMENTS

In the configurations of the embodiments described above, the first region or the second region is disposed between the first branch portion and the second branch portion in the second direction. However, the present disclosure is not limited to this example, and both of the first region and the second region may be disposed between the first branch portion and the second branch portion in the second direction. The first branch portion and the second branch portion may be disposed between the first region and the second region in the second direction.

In the embodiments described above, the outer shape of the substrate is a rectangle when seen in the thickness direction of the substrate. However, the present disclosure is not limited to this example, and the outer shape may be another shape such as a trapezoid, a circle, or an oval.

In the embodiments described above, wires are employed as connection members electrically connecting components. However, the present disclosure is not limited to this example, and ribbon wires or bus bars electrically connecting components may be employed as connection members, for example. In the embodiments described above, the first source wires are employed as the first source connection members. However, the present disclosure is not limited to this example, and ribbons or bus bars electrically connecting components may be employed as first source connection members, for example. In the embodiments described above, the second source wires are employed as the second source connection members. However, the present disclosure is not limited to this example, and ribbons or bus bars electrically connecting components may be employed as second source connection members, for example.

It should be understood that the embodiments disclosed here are illustrative and non-restrictive in every respect. The scope of present disclosure is defined by the terms of the claims, rather than the description above, and is intended to include any modifications within the scope and meaning equivalent to the terms of the claims.

### DESCRIPTION OF REFERENCE NUMERALS

11a, 11b, 11c, 11d, 11e semiconductor device
12 heat dissipation plate
12a surface
13 frame member
13a first wall
13b second wall
13c third wall
13d fourth wall
14a metal plate
15a, 15b, 15c, 15d, 15e, 80a, 80b substrate
16a, 16b, 16c, 16e circuit pattern
17a, 18a solder portion
19a P-terminal
19b, 19c O-terminal
19d N-terminal
20 case
21a, 21b, 21c, 21d first diode chip
21e, 21f, 21g, 21h second diode chip
21i, 21j, 21k, 21l third diode chip
21m, 21n, 21o, 21p fourth diode chip
22a, 22b, 22c, 22d first transistor chip
22e, 22f, 22g, 22h second transistor chip
23a, 23b, 23c, 23d, 24a, 24b, 24c, 24d, 24e, 24f, 24g, 24h, 24i, 24j, 24k, 241, 24m, 24n,
24o, 24p, 25a, 25b, 25c, 25d, 25e, 25f, 25g, 25h, 26a, 26b, 26c, 26d, 26e, 26f, 26g, 29a,
29b, 29c, 29d, 29e, 29f, 29g, 29h, 31a, 31b, 31c, 31d, 31e, 31f, 31g, 31h, 32a, 32b, 32c,
32d, 32e, 32f, 32g, 32h wire
27 inner wall surface
28 thermistor
30 space
33a, 33b longer side
34a, 34b shorter side
41a first gate terminal
41b second gate terminal
42a first kelvin source terminal
42b second kelvin source terminal
44a, 44b thermistor terminal
45 region
51a, 51b, 51c, 51d, 51e, 71b, 71d first region
52a, 52b, 52c, 52d, 52e, 72b, 72d second region
53a, 53b, 53c, 53d, 53e third region
54a, 54b, 54c, 54d, 54e, 74b fourth region
55a, 55b, 55c, 55d, 55e, 75b fifth region
56a, 56b, 56c, 56e, 76b, 76d sixth region
57a, 57b, 57c, 57e, 77b, 77d seventh region
58a, 58b, 58c, 58d, 58e eighth region
59a, 59b, 59c, 59d, 59e ninth region
61a, 61b, 61c, 61d, 61e, 81b, 81d first branch portion
62a, 62b, 62c, 62d, 62e, 82b, 82d second branch portion
63a, 63b, 63c, 63d, 63e connection portion
D1, D2, D3, D4, D5 arrow

1. A semiconductor device comprising:
an insulating substrate;
a circuit pattern disposed on the substrate;
a P-terminal, an N-terminal, and an O-terminal electrically connected to the circuit pattern;
a first transistor chip and a second transistor chip mounted on the circuit pattern; and
a first diode chip and a second diode chip mounted on the circuit pattern, wherein the circuit pattern includes
a band-shaped first region electrically connected to the P-terminal and extending along a first direction,
a band-shaped second region electrically connected to the N-terminal, spaced from the first region in a second direction, and extending along the first direction, the second direction being a width direction of the first region, and
a third region electrically connected to the O-terminal and spaced from each of the first region and the second region,
the third region includes
a band-shaped first branch portion extending along the first direction,
a band-shaped second branch portion spaced from the first branch portion in the second direction and extending along the first direction, and
a connection portion extending along the second direction and connecting one end of the first branch portion and one end of the second branch portion,
the first transistor chip is mounted on the first region to be electrically connected to the first region, and electrically connected to the first branch portion by a first wire,
the second transistor chip is mounted on the second branch portion to be electrically connected to the second branch portion, and electrically connected to the second region by a second wire,
the first diode chip is mounted on the first region to be electrically connected to the first region, and electrically connected to the first branch portion by a connection member,
the second diode chip is mounted on the second branch portion to be electrically connected to the second branch portion, and electrically connected to the second region by a connection member,
the first transistor chip and the first diode chip are disposed side by side along the first direction, and
the second transistor chip and the second diode chip are disposed side by side along the first direction.

2. The semiconductor device according to claim 1, wherein
the first region is divided, in the first direction, into one-side first region disposed at the one side and the other-side first region disposed at the other side, the one-side first region and the other-side first region being disposed side by side along the first direction and electrically connected to each other by a connection member,
the second region is divided, in the first direction, into one-side second region disposed at the one side and the other-side second region disposed at the other side, the one-side second region and the other-side second region being disposed side by side along the first direction and electrically connected to each other by a connection member,
the first branch portion is divided, in the first direction, into one-side first branch portion disposed at the one side and the other-side first branch portion disposed at the other side, the one-side first branch portion and the other-side first branch portion being disposed side by side along the first direction and electrically connected to each other by a connection member, and
the second branch portion is divided, in the first direction, into one-side second branch portion disposed at the one side and the other-side second branch portion disposed at the other side, the one-side second branch portion and the other-side second branch portion being disposed side by side along the first direction and electrically connected to each other by a connection member.

3. The semiconductor device according to claim 12, further comprising a plurality of third diode chips and a plurality of fourth diode chips mounted on the circuit pattern, wherein
the plurality of third diode chips are adjacent to one another along the first direction, disposed side by side with the first diode chip in the second direction, mounted on the first region to be electrically connected to the first region, and electrically connected to the first branch portion by a connection member, and
the plurality of fourth diode chips are adjacent to one another along the first direction, disposed side by side with the third diode chip in the second direction, mounted on the second branch portion to be electrically connected to the second branch portion, and electrically connected to the second region by a connection member.

4. The semiconductor device according to claim 1, wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips are adjacent to one another along the first direction,
the plurality of second transistor chips are adjacent to one another along the first direction,
the plurality of first diode chips are adjacent to one another along the first direction, and
the plurality of second diode chips are adjacent to one another along the first direction.

5. The semiconductor device according to claim 4, wherein
the plurality of first transistor chips are mounted on the one-side first region,
the plurality of first diode chips are mounted on the other-side first region,
the plurality of second transistor chips are mounted on the other-side second branch portion, and
the plurality of second diode chips are mounted on the one-side second branch portion.

6. The semiconductor device according to claim 5, wherein
the plurality of third diode chips are mounted on the other-side first region, and the plurality of fourth diode chips are mounted on the one-side second branch portion.

7. The semiconductor device according to claim 1, wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips and the plurality of first diode chips are alternately arranged along the first direction, and
the plurality of second transistor chips and the plurality of second diode chips are alternately arranged along the first direction.

8. The semiconductor device according to claim 1, further comprising:
a heat dissipation plate having a first surface at one side in a thickness direction of the substrate, the substrate being mounted on the first surface; and
a frame member rising from the first surface and surrounding the substrate when seen in the thickness direction of the substrate, wherein
an outer shape of the substrate is a rectangle whose pair of longer sides extends in the first direction when seen in the thickness direction of the substrate,
the frame member includes a first wall and a second wall respectively corresponding to the pair of longer sides of the substrate,
the P-terminal and the N-terminal are disposed at a side opposite to a second shorter side when seen from a first shorter side of the substrate, and
the O-terminal is disposed at a side opposite to the first shorter side when seen from the second shorter side.

9. The semiconductor device according to claim 8, further comprising:
a first gate terminal attached to the first wall and electrically connected to a gate pad of the first transistor chip; and
a second gate terminal attached to the second wall and electrically connected to a gate pad of the second transistor chip, wherein
in the second direction, a distance between the first wall and the first region is smaller than each of a distance between the first wall and the second region, a distance between the first wall and the first branch portion, and a distance between the first wall and the second branch portion, and
in the second direction, a distance between the second wall and the second branch portion is smaller than each of a distance between the second wall and the first region, a distance between the second wall and the second region, and a distance between the second wall and the first branch portion.

10. The semiconductor device according to claim 8, further comprising:
a first kelvin source terminal attached to the first wall and electrically connected to a kelvin source pad of the first transistor chip; and
a second kelvin source terminal attached to the second wall and electrically connected to a kelvin source pad of the second transistor chip, wherein
in the second direction, a distance between the first wall and the first region is smaller than each of a distance between the first wall and the second region, a distance between the first wall and the first branch portion, and a distance between the first wall and the second branch portion, and
in the second direction, a distance between the second wall and the second branch portion is smaller than each of a distance between the second wall and the first region, a distance between the second wall and the second region, and a distance between the second wall and the first branch portion.

11. The semiconductor device according to claim 10, wherein
the first gate terminal and the first kelvin source terminal are adjacent to each other and attached to the first wall,
the second gate terminal and the second kelvin source terminal are adjacent to each other and attached to the second wall,
the circuit pattern further includes
a band-shaped fourth region electrically connected to the first kelvin source terminal by a connection member, spaced from the first region in the second direction, and extending along the first direction,
a band-shaped fifth region electrically connected to the first gate terminal by a connection member, spaced from the fourth region in the second direction, and extending along the first direction,
a band-shaped sixth region electrically connected to the second gate terminal by a connection member, spaced from the second branch portion in the second direction, and extending along the first direction, and
a band-shaped seventh region electrically connected to the second kelvin source terminal by a connection member, spaced from the sixth region in the second direction, and extending along the first direction,
a current direction from the first gate terminal to a gate pad of the first transistor chip in the fifth region is opposite to a current direction from the kelvin source pad of the first transistor chip to the first kelvin source terminal in the fourth region, and
a current direction from the second gate terminal to a gate pad of the second transistor chip in the sixth region is opposite to a current direction from the kelvin source pad of the second transistor chip to the second kelvin source terminal in the seventh region.

12. The semiconductor device according to claim 1, wherein
the first wire includes first source connection members each electrically connecting a source pad of the first transistor chip to the first branch portion,
the second wire includes second source connection members each electrically connecting a source pad of the second transistor chip to the second region,
a length of each of the first source connection members is equal to a length of each of the second source connection members, and
the number of the first source connection members is equal to the number of the second source connection members.

13. The semiconductor device according to claim 1, wherein at least one of the first transistor chip or the second transistor chip includes a semiconductor layer of SiC or GaN.

14. The semiconductor device according to claim 1, wherein
the first branch portion is disposed between the first region and the second region in the second direction, and
the second region is disposed between the first branch portion and the second branch portion in the second direction.

15. The semiconductor device according to claim 2, further comprising a plurality of third diode chips and a plurality of fourth diode chips mounted on the circuit pattern, wherein
the plurality of third diode chips are adjacent to one another along the first direction, disposed side by side with the first diode chip in the second direction, mounted on the first region to be electrically connected to the first region, and electrically connected to the first branch portion by a connection member, and
the plurality of fourth diode chips are adjacent to one another along the first direction, disposed side by side with the third diode chip in the second direction, mounted on the second branch portion to be electrically connected to the second branch portion, and electrically connected to the second region by a connection member.

16. The semiconductor device according to claim 2, wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips are adjacent to one another along the first direction,
the plurality of second transistor chips are adjacent to one another along the first direction,
the plurality of first diode chips are adjacent to one another along the first direction, and
the plurality of second diode chips are adjacent to one another along the first direction.

17. The semiconductor device according to claim 3 wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips are adjacent to one another along the first direction,
the plurality of second transistor chips are adjacent to one another along the first direction,
the plurality of first diode chips are adjacent to one another along the first direction, and
the plurality of second diode chips are adjacent to one another along the first direction.

18. The semiconductor device according to claim 2, wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips and the plurality of first diode chips are alternately arranged along the first direction, and
the plurality of second transistor chips and the plurality of second diode chips are alternately arranged along the first direction.

19. The semiconductor device according to claim 3, wherein
the first transistor chip includes a plurality of first transistor chips,
the second transistor chip includes a plurality of second transistor chips,
the first diode chip includes a plurality of first diode chips,
the second diode chip includes a plurality of second diode chips,
the plurality of first transistor chips and the plurality of first diode chips are alternately arranged along the first direction, and
the plurality of second transistor chips and the plurality of second diode chips are alternately arranged along the first direction.

20. The semiconductor device according to claim 2, further comprising:
a heat dissipation plate having a first surface at one side in a thickness direction of the substrate, the substrate being mounted on the first surface; and
a frame member rising from the first surface and surrounding the substrate when seen in the thickness direction of the substrate, wherein
an outer shape of the substrate is a rectangle whose pair of longer sides extends in the first direction when seen in the thickness direction of the substrate,
the frame member includes a first wall and a second wall respectively corresponding to the pair of longer sides of the substrate,
the P-terminal and the N-terminal are disposed at a side opposite to a second shorter side when seen from a first shorter side of the substrate, and
the O-terminal is disposed at a side opposite to the first shorter side when seen from the second shorter side.
